(19) United States
(12) Patent Application Publication
(10) Pub. No.: US 2020/0408598 A1
(43) Pub. Date: Dec. 31, 2020

(54) SENSOR DEVICE AND ELECTRONIC DEVICE

(71) Applicant: SONY SEMICONDUCTOR SOLUTIONS CORPORATION, KANAGAWA (JP)

(72) Inventors: ATSUSHI TODA, KANAGAWA (JP); HYUNSUNG PARK, KANAGAWA (JP)

(21) Appl. No.: 16/968,716

(22) PCT Filed: Feb. 1, 2019
(86) PCT No.: PCT/JP2019/003553

§ 371 Date: Aug. 10, 2020

(30) Foreign Application Priority Data
Feb. 16, 2018 (JP) 2018-025960

(51) Int. Cl. G01J 3/42; G01J 3/26; G01J 3/51; G02B 1/118; H01L 27/146

(52) U.S. Cl. CPC G01J 3/42; G01J 3/26; G01J 3/51; H04N 9/0455; H01L 27/14627; H01L 27/14621; G02B 1/118

(57) ABSTRACT

The present disclosure relates to a sensor device and an electronic device capable of providing a better spectral characteristic. A sensor device is provided with a semiconductor substrate on which a photodiode is formed, a filter included in a multilayer structure stacked on a light-receiving surface side of the semiconductor substrate, and a moth-eye structure arranged on an outermost surface above the filter. Then, a surface plasmon resonance filter or a Fabry-Perot resonator filter is used as the filter. The present technology may be applied to, for example, a spectral device which performs multi-spectroscopy or hyperspectral spectroscopy.

### TECHNICAL FIELD

The present disclosure relates to a sensor device and an electronic device, and especially relates to a sensor device and an electronic device capable of providing a better spectral characteristic.

### BACKGROUND ART

Conventionally, a sensor device capable of performing multi-spectroscopy may perform spectroscopy into a plurality of spectral components in multiple bands of three primary colors of light or more by using, for example, a surface plasmon resonance filter, a filter of a Fabry-Perot resonator or the like. However, in such sensor device, a ripple (oscillation) might occur in a spectrum due to interference between reflected light on a surface and reflected light from a lower layer. Since such ripple is different from an original desired spectrum, this adversely affects multi-wavelength separation.

For example, Patent Document 1 discloses an imaging element provided with a filter including a plasmon resonator which is a conductor metal structure having an irregular structure at predetermined intervals.

### CITATION LIST

### Patent Document

### Patent Document 1: Japanese Patent Application Laid-Open No. 2012-59865

### SUMMARY OF THE INVENTION

### Problems to be Solved by the Invention

As described above, conventionally, the ripple occurring in the spectrum cannot be effectively suppressed, and it has been difficult to obtain an original spectral characteristic of a filter.

The present disclosure is achieved in view of such a situation, and an object thereof is to provide a better spectral characteristic

### Solutions to Problems

A sensor device according to one aspect of the present disclosure is provided with a semiconductor substrate on which a photodiode is formed, a filter included in a multilayer structure stacked on a light-receiving surface side of the semiconductor substrate, and a moth-eye structure arranged on an outermost surface above the filter.

An electronic device according to one aspect of the present disclosure is provided with a sensor device including a semiconductor substrate on which a photodiode is formed, a filter included in a multilayer structure stacked on a light-receiving surface side of the semiconductor substrate, and a moth-eye structure arranged on an outermost surface above the filter.

In one aspect of the present disclosure, a filter is included in a multilayer structure stacked on a light-receiving surface side of a semiconductor substrate on which a photodiode is formed, and a moth-eye structure is arranged on an outermost surface above the filter.

### Effects of the Invention

According to one aspect of the present disclosure, a better spectral characteristic may be provided.

Note that, the effects are not necessarily limited to the effects herein described and may be the effects described in the present disclosure.

### BRIEF DESCRIPTION OF DRAWINGS

FIG. 1 is a view illustrating occurrence of a ripple.

FIG. 2 is a view illustrating an example of avoiding the occurrence of a ripple by an on-chip lens structure.

FIG. 3 is a cross-sectional view illustrating a configuration example of a first embodiment of a sensor chip to which the present technology is applied.

FIG. 4 is a view illustrating a moth-eye structure.

FIG. 5 is a view illustrating a surface plasmon resonance filter and a spectral sensitivity characteristic.

FIG. 6 is a cross-sectional view illustrating a second configuration example of a sensor chip.

FIG. 7 is a view illustrating components of a Fabry-Perot resonator.

FIG. 8 is a view illustrating a structure of the Fabry-Perot resonator.

FIG. 9 is a view illustrating an example of a film type, a thickness, and the number of layers of the Fabry-Perot resonator.

FIG. 10 is a view illustrating a multi-transmission spectral characteristic of visible light.

FIG. 11 is a view illustrating a multi-transmission spectral characteristic of near-infrared light.

FIG. 12 is a view illustrating an example of periodical arrangement of spectral components by a filter.

FIG. 13 is a cross-sectional view of four pixels of a sensor chip which uses a surface plasmon resonance filter.

FIG. 14 is a view illustrating an arrangement example of a fine structure forming the surface plasmon resonance filter.

FIG. 15 is a cross-sectional view of four pixels of a sensor chip which uses a Fabry-Perot resonator.

FIG. 16 is a view illustrating a manufacturing method of a sensor chip.

FIG. 17 is a view illustrating another manufacturing method of a sensor chip.

FIG. 18 is a cross-sectional view illustrating a third configuration example of a sensor chip.

FIG. 19 is a cross-sectional view illustrating a fourth configuration example of a sensor chip.

FIG. 20 is a view illustrating a spectral characteristic of reflectance depending on a plant state.

FIG. 21 is a view illustrating a spectral characteristic of reflectance of human skin.

FIG. 22 is a block diagram illustrating a configuration example of one embodiment of an imaging element to which the present invention is applied.

FIG. 23 is a block diagram illustrating a configuration example of an imaging device.

FIG. 24 is a view illustrating a usage example to use an image sensor.

FIG. 25 is a diagram illustrating an outline of a configuration example of a stacked solid-state imaging device to which the technology according to the present disclosure is applicable.

FIG. 26 is a cross-sectional view illustrating a first configuration example of a stacked solid-state imaging device 23020.

FIG. 27 is a cross-sectional view illustrating a second configuration example of the stacked solid-state imaging device 23020.

FIG. 28 is a cross-sectional view illustrating a third configuration example of the stacked solid-state imaging device 23020.

FIG. 29 is a cross-sectional view illustrating another configuration example of a stacked solid-state imaging device to which the technology according to the present disclosure is applicable.

FIG. 30 is a view illustrating an example of a schematic configuration of an endoscopic surgery system.

FIG. 31 is a block diagram illustrating an example of a functional configuration of a camera head and a CCU.

FIG. 32 is a block diagram illustrating an example of a schematic configuration of a vehicle control system.

FIG. 33 is an illustrative view illustrating an example of an installation position of a vehicle exterior information detecting unit and an imaging unit.

### MODE FOR CARRYING OUT THE INVENTION

Hereinafter, a specific embodiment to which the present technology is applied is described in detail with reference to the drawings.

<Regarding Ripple>

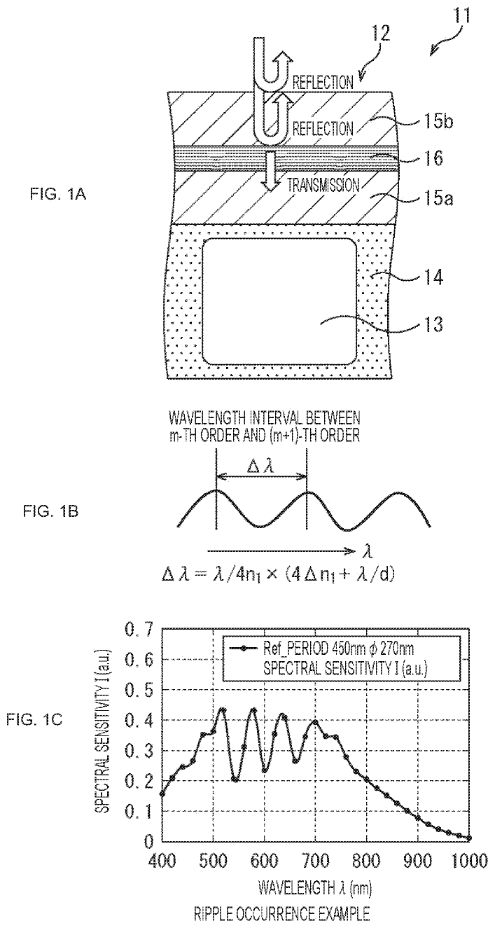

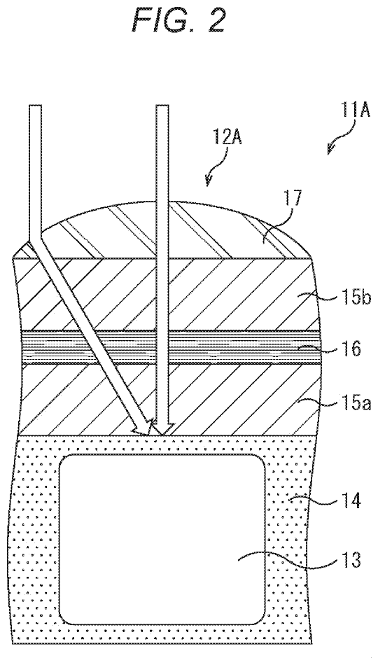

First, a ripple is described with reference to FIGS. 1 and 2.

A of FIG. 1 illustrates a cross-sectional configuration of one pixel 12 included in a conventional sensor chip 11 having a multispectral structure. As illustrated, the sensor chip 11 is formed by stacking a filter 16 so as to be interposed between silicon oxide films 15a and 15b on a semiconductor substrate 14 in which a photodiode 13 is formed. Furthermore, a surface plasmon resonance filter or a Fabry-Perot resonator filter is used as the filter 16 for performing multi-spectroscopy.

Here, in a structure in which a surface of the sensor chip 11 is flat (structure without an on-chip lens 17 as illustrated in FIG. 2), a ripple occurs in a spectrum due to interference of a strengthening condition and a weakening condition due to a phase difference between two reflected light beams: reflected light on the surface of the sensor chip 11 and reflected light in the sensor chip 11. Therefore, the ripple is superimposed on an original spectrum of the filter 16, thereby adversely affecting a spectral characteristic.

For example, as one means for avoiding the occurrence of such ripple, there is a structure in which the on-chip lens 17 is provided on a surface of a pixel 12A as illustrated in a sensor chip 11A in FIG. 2. However, in the structure provided with the on-chip lens 17, an original spectral characteristic of the filter 16 is destroyed due to an increase in oblique incident component. Therefore, it becomes difficult to narrow by signal processing.

Here, a cause of the ripple occurrence is further described.

As illustrated in A of FIG. 1, one light is reflected by two interfaces at refractive index steps to be divided into two light beams, and when the reflected light beams are overlapped, light interference occurs. At that time, a phase difference due to a difference in optical path length of the two light beams and presence or absence of phase inversion due to reflection determine the phase difference; it is strengthened in a case of the same phase, and it is weakened in a case of shifting by half a phase. For example, the phase inversion occurs at the time of interface reflection from a low refractive index to a high refractive index, but in contrast, the phase inversion does not occur at the time of interface reflection from a high refractive index to a low refractive index. Reflection R becomes higher or lower by this interference. At the same time, transmission T also becomes higher or lower in conjunction with the reflection R because this follows an energy conservation law (T=1−R).

Furthermore, as illustrated in C of FIG. 1, even with a change in wavelength, strengthening and weakening similarly occur in the interference.

At that time, for a wavelength interval AA between an m-th order and an (m+1)-th order which is the strengthening condition, a mathematical expression as illustrated in B of FIG. 1 is established. Here, n1 represents a refractive index of the silicon oxide film 15b, and Δn1 represents a wavelength dispersion characteristic of the refractive index. Furthermore, d represents a thickness of the silicon oxide film 15b. Therefore, the larger the thickness d and the smaller the refractive index dispersion Δn1, the shorter an oscillation period. The ripple of the spectrum is the oscillation of the spectrum.

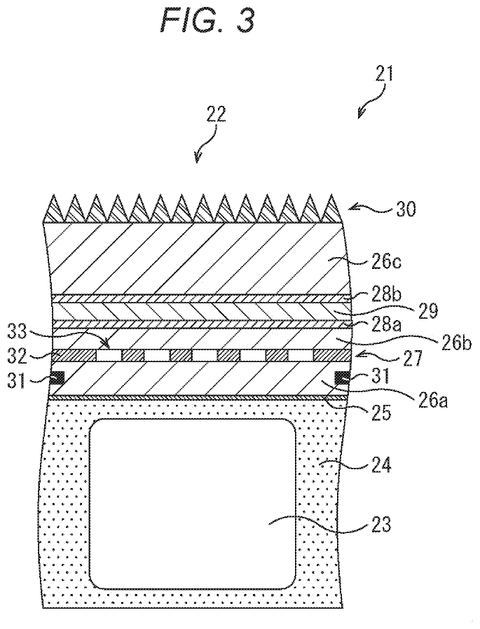

Therefore, in order to fundamentally reduce the ripple, it is necessary to weaken an interference effect. Therefore, a sensor chip 21 illustrated in FIG. 3 to be described later reduces the ripple by weakening surface reflected light out of the two interfering light beams.

Furthermore, for example, it is considered to suppress the occurrence of ripple by using an on-chip lens.

With reference to FIG. 2, a structure of suppressing the occurrence of ripple by using the on-chip lens is described. Note that, in FIG. 2, for simplifying description, a case where parallel light beams are incident on the pixel 12A in a perpendicular direction is described as an example.

At that time, light perpendicularly incident on the on-chip lens 17 near the center thereof as seen from above is perpendicularly incident thereon as is, whereas light deviated from the center of the on-chip lens 17 is obliquely incident on a surface of the on-chip lens 17, so that this is refracted on the surface and obliquely incident thereon. Therefore, since an optical path length of oblique incidence changes with respect to an optical path length of perpendicular incidence, the ripple of the spectrum causes a wavelength shift.

Therefore, since light beams of different ripple spectrum are simultaneously incident on one photodiode 13, the ripple is seemed to be relaxed due to integration; the interference effect is not weakened. Moreover, the original filter spectrum is destroyed by an obliquely incident component. Therefore, in the surface plasmon resonance filter, a peak wavelength causes a long wavelength shift due to the oblique incidence to change to a broad spectrum as a totality. Furthermore, in the Fabry-Perot resonator filter, a short wavelength shift occurs due to the oblique incidence, and broadening occurs similarly.

In contrast to such sensor chip 11A, the sensor chip 21 to be described below may suppress the occurrence of ripple in a flat configuration without using the on-chip lens 17. Therefore, the sensor chip 21 has the spectrum of the original filter characteristic, so that the signal processing may be narrowed. Note that, in this embodiment, the flat configuration without using the on-chip lens 17 is intended to mean that an outermost surface is flat, but a surface with unevenness equal to or smaller than a wavelength of light may be regarded to be optically flat, and regarded as an effectively flat surface.

<First Configuration Example of Sensor Chip>

FIG. 3 is a cross-sectional view illustrating a configuration example of a first embodiment of the sensor chip to which the present technology is applied.

For example, the sensor chip 21 is formed such that a plurality of pixels 22 is arranged into an array. FIG. 3 illustrates a cross-sectional configuration of one pixel 22, and a photodiode 23 of a pn junction is formed in a semiconductor substrate 24 for each pixel 22. Then, the sensor chip 21 is formed by stacking an antireflection film 25, a silicon oxide film 26a, a surface plasmon resonance filter 27, a silicon oxide film 26b, a silicon oxynitride film 28a, a silicon nitride film 29, a silicon oxynitride film 28b, a silicon oxide film 26c, and a moth-eye structure 30 in this order from a side of the semiconductor substrate 24.

The antireflection film 25 is formed, for example, by depositing hafnium oxide, silicon nitride and the like on a surface of the semiconductor substrate 24, and prevents reflection of light by the surface of the semiconductor substrate 24.

The silicon oxide (SiO2) films 26a to 26c are insulating films having an insulating property, and insulate other stacked layers from each other. Furthermore, in the silicon oxide film 26a, a light-shielding film 31 for blocking light leakage and preventing color mixing between the pixels 22 is formed.

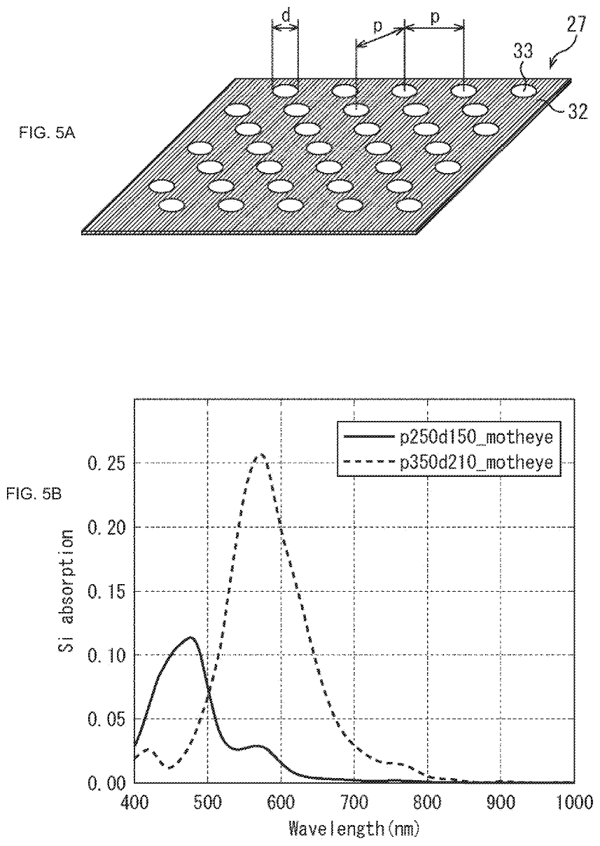

As is described later with reference to FIG. 5, the surface plasmon resonance filter 27 is obtained by forming periodic fine structures 33 on an aluminum film 32, and may perform spectroscopy into a plurality of spectral components in multiple bands of three primary colors of light or more.

A stacked structure obtained by interposing the silicon nitride (Si3N4) film 29 between the silicon oxynitride (SiON) films 28a and 28b is used as a passivation film for protecting the aluminum film 32 of the surface plasmon resonance filter 27 from oxidation.

The moth-eye structure 30 suppresses reflectance on a surface of the sensor chip 21 above the surface plasmon resonance filter 27 to 1% or less. That is, the moth-eye structure 30 is used to weaken the interference effect above the surface plasmon resonance filter 27.

As described above, an interference phenomenon is interference between the reflected light beams, so that if one reflected light is weakened, coherency may be lost. As a general means for reducing the reflectance, there is a method of forming an antireflection film (for example, thickness d=λ/4 n) on an outermost surface. However, even if such antireflection film is provided, there is several percent of reflectance, so that this is not sufficient to lose coherency. In contrast, the sensor chip 21 may lose coherency by a structure in which the moth-eye structure 30 which suppresses the reflectance to 1% or less is arranged on the outermost surface.

Here, the sensor chip 21 is configured such that the outermost surface thereof is flat supposing that the moth-eye structure 30 is removed. Alternatively, the sensor chip 21 is configured such that a virtual surface obtained by connecting points at tips of the moth-eye structure 30 is flat. That is, a substrate surface of the sensor chip 21 may be defined to be effectively flat unlike the configuration provided with the on-chip lens 17 as illustrated in FIG. 2.

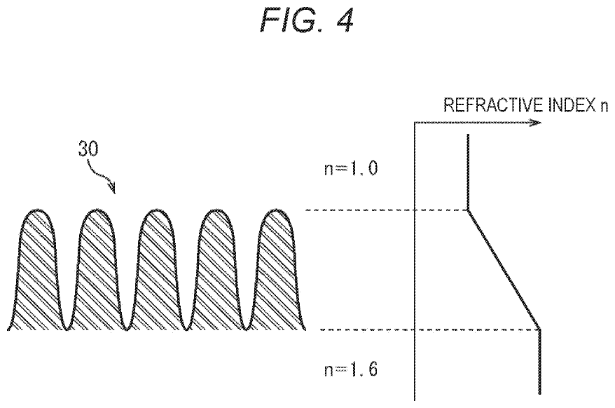

For example, the moth-eye structure 30 is a structure in which a large number of projections having a pointed shape are arranged at a pitch of wavelength λ or smaller (especially ⅓×λ or smaller). However, as illustrated in FIG. 4, even if the tip of the moth-eye structure 30 is dull to some extent, this is still effective.

Furthermore, as illustrated in FIG. 4, an effective refractive index of the moth-eye structure 30 is smoothly continuous from a refractive index n=1.0 of air to a refractive index n=1.6 of a substrate, and there is no interface. Therefore, since there is no reflection interface, the reflectance is significantly reduced.

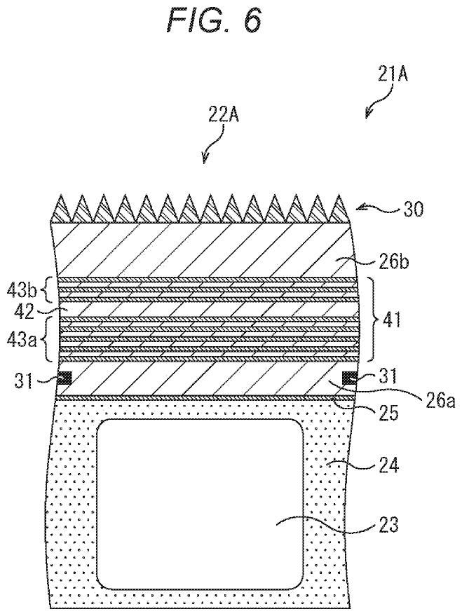

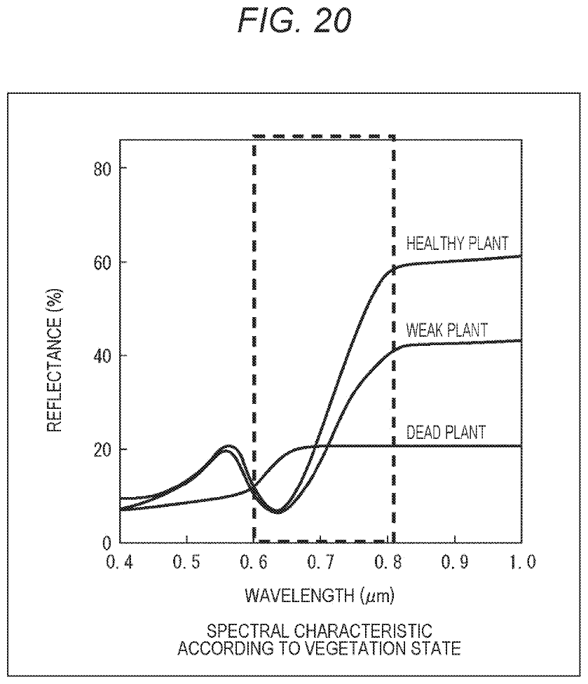

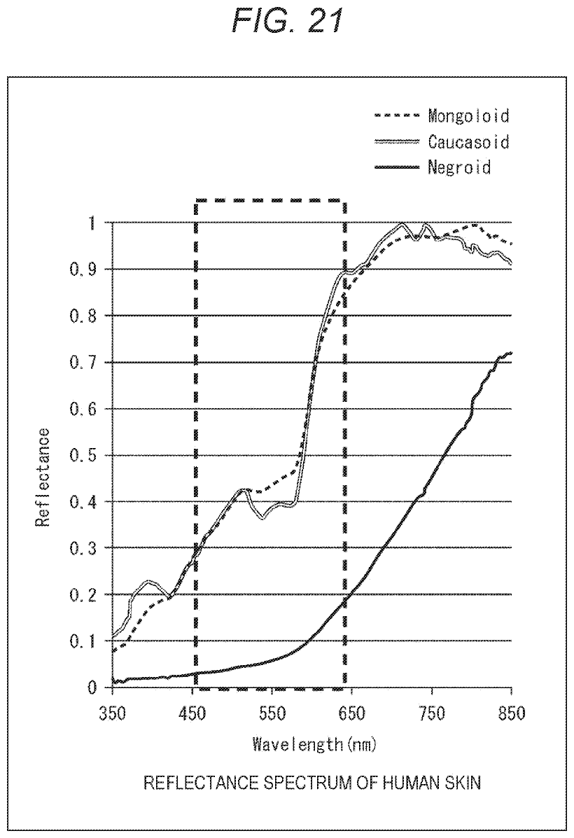

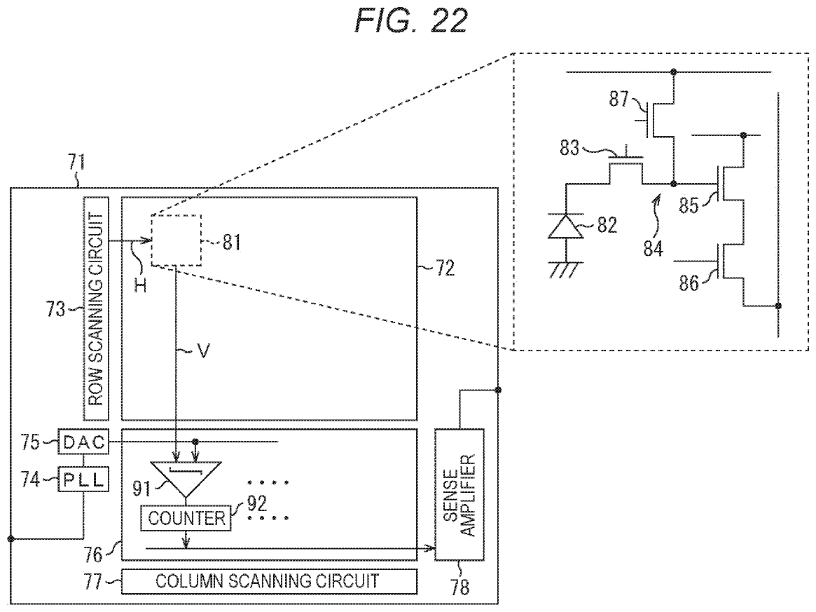

The sensor chip 21 configured in this manner may almost completely suppress the occurrence of ripple in a spectral sensitivity characteristic even if the outermost surface thereof has a flat structure. Especially, the sensor chip 21 may suppress the ripple which is an external factor while maintaining the original spectral characteristic of the filter in multi-spectroscopy using the surface plasmon resonance filter (or a Fabry-Perot resonator 41 in FIG. 6 to be described later), so that accurate color information, spectral information and the like may be obtained. Therefore, the sensor chip 21 may be appropriately used for various applications such as agriculture and living body authentication to be described later with reference to FIGS. 20 and 21, for example.

<Regarding Surface Plasmon Resonance Filter>

The surface plasmon resonance filter 27 is described with reference to FIG. 5.

As illustrated in A of FIG. 5, the surface plasmon resonance filter 27 has a structure in which holes serving as the fine structures 33 are periodically formed on the aluminum film 32, and it is possible to change a transmission spectrum of the filter and its peak wavelength by changing a period p and diameters d of the fine structures 33. Note that, in addition to the aluminum film 32, a metal film such as gold or silver may be used as the surface plasmon resonance filter 27. Furthermore, a dielectric such as an oxide film may be present in upper and lower layers of the surface plasmon resonance filter 27 and the holes of the fine structures 33.

For example, in the structure of the sensor chip 21 illustrated in FIG. 3, the holes serving as the fine structures 33 of the surface plasmon resonance filter 27 are filled with the silicon oxide films 26a and 26b in upper and lower layers thereof.

Furthermore, B of FIG. 5 illustrates a result of simulation of the spectral sensitivity characteristic when light is incident from above on the sensor chip 21 including the surface plasmon resonance filter 27 and including the moth-eye structure 30 in which the on-chip lens is not provided and the surface is effectively flat as described above by a 3D finite-difference time-domain (FDTD) method.

As illustrated, this simulation indicates that, in the sensor chip 21, the ripple is improved, so that this has the original spectral characteristic of the surface plasmon resonance filter 27.

<Second Configuration Example of Sensor Chip>

With reference to FIGS. 6 to 12, the sensor chip 21 of the second configuration example that performs the multi-spectroscopy by the Fabry-Perot resonator is described.

FIG. 6 illustrates a cross-sectional configuration example of a sensor chip 21A configured to perform the multi-spectroscopy by the Fabry-Perot resonator 41. Note that, in the sensor chip 21A illustrated in FIG. 6, the same reference sign is given to a configuration common to that of the sensor chip 21 in FIG. 3, and the detailed description thereof is not repeated.

As illustrated in FIG. 6, the sensor chip 21A has a configuration provided with the Fabry-Perot resonator 41 in place of the stacked structure from the surface plasmon resonance filter 27 to the silicon oxynitride film 28b of the sensor chip 21 in FIG. 3.

The Fabry-Perot resonator 41 has a structure in which a resonator 42 is interposed between half mirror layers 43a and 43b, and may perform spectroscopy into a plurality of spectral components in multiple bands of three primary colors of light or more.

Each of the half mirror layers 43a and 43b is formed by using a multilayer film of a titanium oxide (TiO2) film and a silicon oxide (SiO2) film. Note that, as the half mirror layers 43a and 43b, a material thereof is not limited as long as this is a multilayer film obtained by combining a material having a high refractive index and a material having a low refractive index in addition to the multilayer film of the titanium oxide film and the silicon oxide film. Furthermore, as the half mirror layers 43a and 43b, a configuration of a metal thin film may be used, for example, in addition to a configuration of the multilayer film.

The resonator 42 is formed by using a silicon oxide (SiO2) film and the Fabry-Perot resonator 41 serves as a filter which passes only light of a specific wavelength by a thickness of the resonator 42 interposed between the half mirror layers 43a and 43b.

Then, as is the case with the sensor chip 21 in FIG. 3, the sensor chip 21A is provided with the moth-eye structure 30 on an outermost surface above the Fabry-Perot resonator 41, and a substrate surface thereof may be defined to be effectively flat. Therefore, as is the case with the sensor chip 21 in FIG. 3, the sensor chip 21A may almost completely suppress the occurrence of ripple in the spectral sensitivity characteristic even with the structure with the flat outermost surface, and may maintain the original spectral characteristic of the filter.

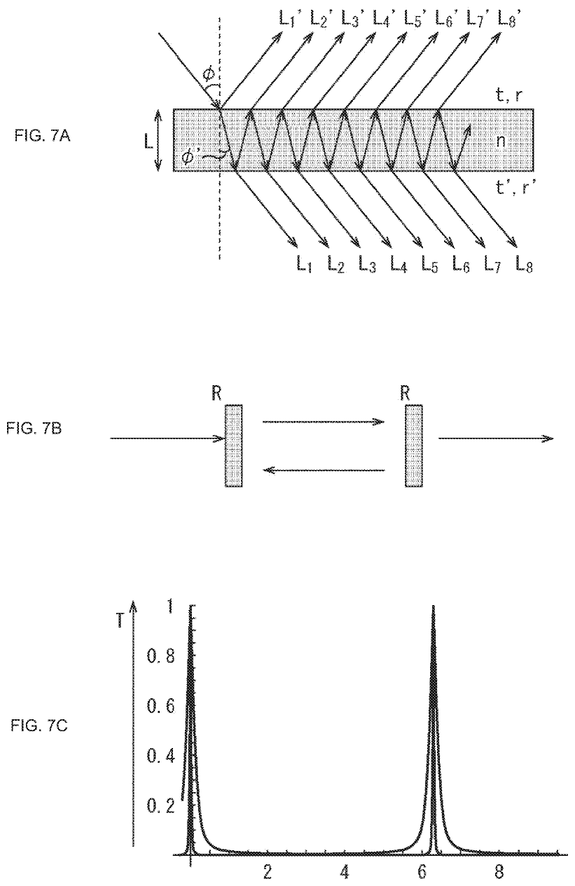

Components of the Fabry-Perot resonator 41 are described with reference to FIG. 7.

As an optical element which selectively transmits only a specific wavelength, a Fabry-Perot etalon as illustrated in A of FIG. 7 and a Fabry-Perot resonator as illustrated in B of FIG. 7 are known, and its transmission spectrum is illustrated in C of FIG. 7.

The Fabry-Perot etalon illustrated in A of FIG. 7 is obtained by polishing both end faces of a glass material having a refractive index larger than that of air, and the end face serves as a half mirror. When light is incident on this, as a result of light interference, only light of a specific wavelength is reflected/transmitted. Utilizing such an optical characteristic, this is used as an optical component such as a wavelength monitor of a semiconductor laser for optical communication.

Furthermore, a Fabry-Perot resonator illustrated in B of FIG. 7 is an optical device especially used while allowing light to be incident perpendicularly on the half mirror in the Fabry-Perot etalon. Light interference also occurs in the Fabry-Perot resonator, and wavelength selectivity appears in transmittance as illustrated in C of FIG. 7. This interference is used, for example, in a resonator of a semiconductor laser.

Furthermore, in recent years, a configuration in which such Fabry-Perot type optical element is mounted on a complementary metal oxide semiconductor (CMOS) image sensor is developed.

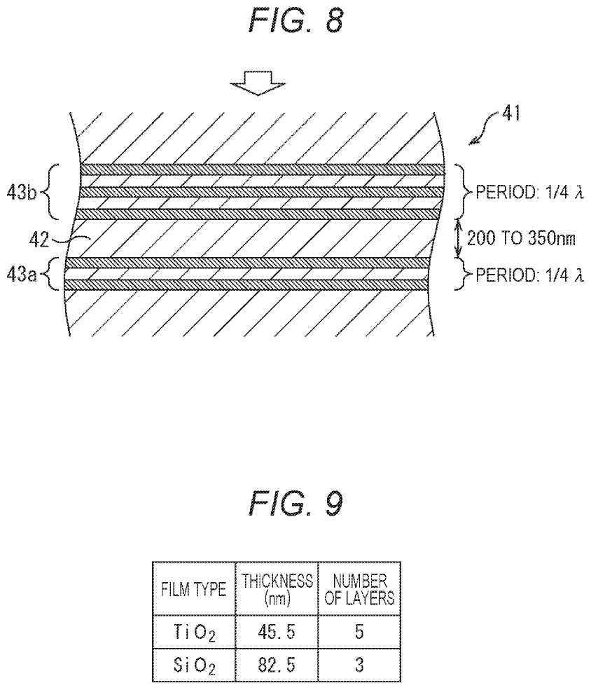

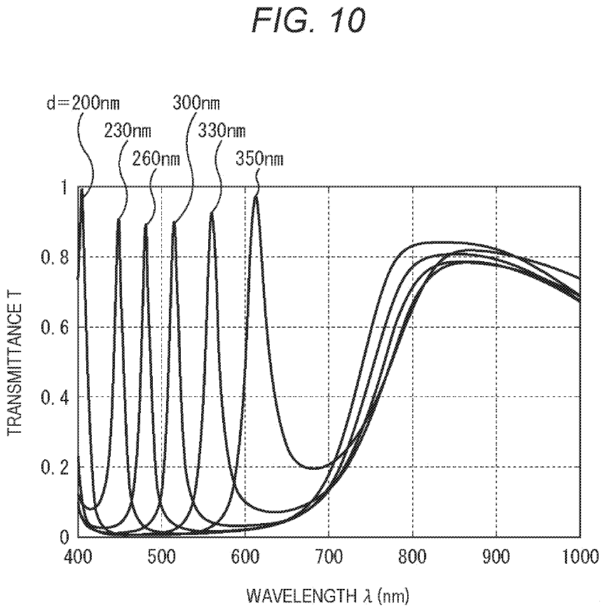

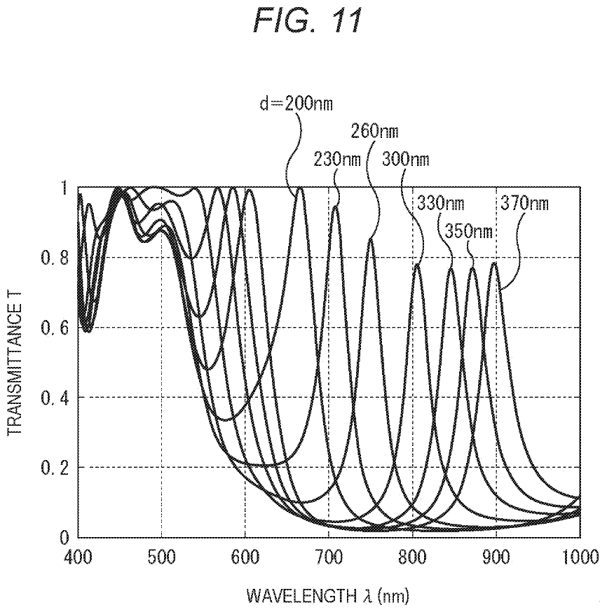

Here, as for the Fabry-Perot resonator 41 having a structure illustrated in FIGS. 8 and 9, a multi-transmission spectral characteristic of visible light is illustrated in FIG. 10.

That is, a transmission spectrum of a configuration in which the half mirror layer 43b includes silicon oxide films more than those of the half mirror layer 43a by one layer in a periodic structure (¼ λ multilayer film) which blocks visible light as illustrated in FIGS. 8 and 9 is illustrated in FIG. 10.

FIG. 10 illustrates that, for example, when a thickness d of the resonator 42 is set to 200 to 350 nm, it is possible to obtain only one peak in a visible light region of a wavelength range of 400 to 650 nm, and a peak wavelength becomes longer as the resonator 42 is made thicker. Furthermore, it is illustrated that a full width at half maximum (FWHM) of the peak becomes as narrow as 15 to 25 nm. Especially, by designing the thickness d of one layer of the silicon oxide film in a range of 200 to 370 nm, it is possible to design the transmission spectrum of visible light having only one peak.

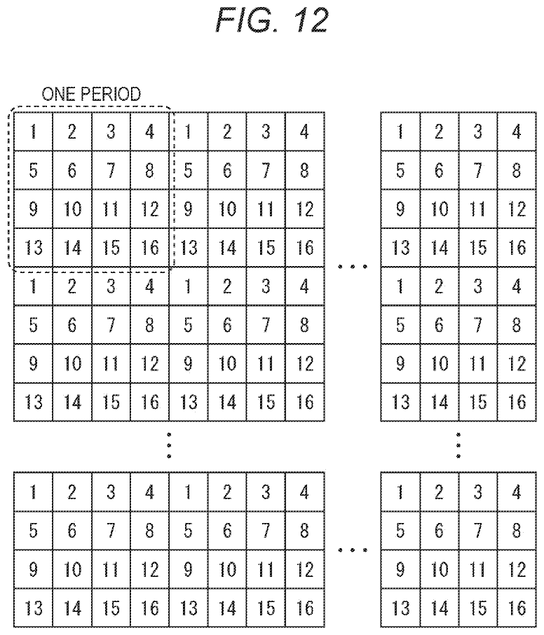

Furthermore, FIG. 11 illustrates a transmission spectrum of perpendicular incidence (6=0 deg) in a case where only one layer of a silicon oxide film having a periodic structure (multilayer film of ¼ λ) which blocks near infrared light is thickened (thickness d).

FIG. 11 illustrates that, for example, by setting the thickness d of the resonator 42 to 200 to 370 nm, there is only one transmission peak in a near infrared light region of wavelength of 650 to 950 nm, and the thicker the thickness, the more the peak wavelength is shifted to a long wavelength side. At that time, by simultaneously arranging a bandpass filter or a black color filter which blocks visible light and transmits infrared light above, infrared spectroscopy of only a selective peak wavelength becomes possible. For example, the full width at half maximum FWHM of the peak is 25 to 40 nm.

Here, a result by thickness modulation of the silicon oxide film which is a material having a low refractive index is illustrated, but a similar effect may be obtained by thickness modulation of a titanium oxide film which is a material having a high refractive index.

Then, the sensor chip 21A has a configuration in which the moth-eye structure 30 illustrated in FIG. 6 is provided on the outermost surface above such Fabry-Perot resonator 41. Therefore, by designing the filter of the Fabry-Perot resonator 41 in which only one layer of the multilayer film of a period which blocks the near-infrared light region or the visible light region is thickened, it becomes possible to allow the near-infrared light region or the visible light region to have a single transmission peak, and control the peak wavelength by the thickness d of the resonator 42.

<Filter Periodic Arrangement>

Periodic arrangement of spectral components by the surface plasmon resonance filter 27 and the Fabry-Perot resonator 41 is described with reference to FIGS. 12 to 16.

For example, in FIG. 12, 16 spectral components of 4×4 vertically and horizontally enclosed by a broken line is made a repeating pattern for one period, and the repeating patterns for one period are continuously arranged in vertical and horizontal directions. Note that, the repeating pattern for one period may be n×n (n is a natural number) such as 5×5 and 6×6 in addition to 4×4.

By applying signal processing to such a plurality of spectral components, a multispectral image is obtained by the sensor chip 21 or 21A. Moreover, it is possible to apply the same from multispectral signal detection to various applications such as agriculture (refer to FIG. 20) and living body detection (refer to FIG. 21).

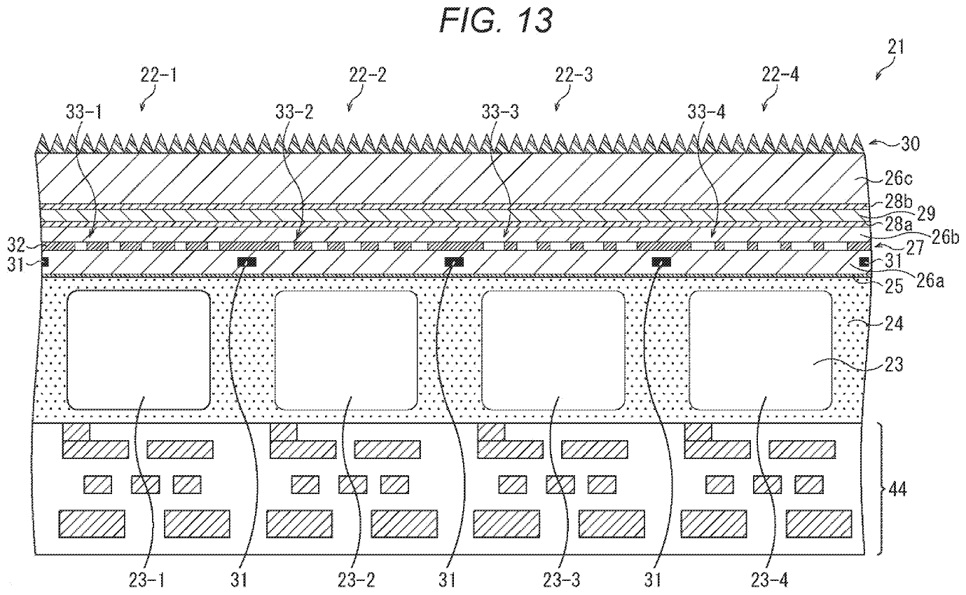

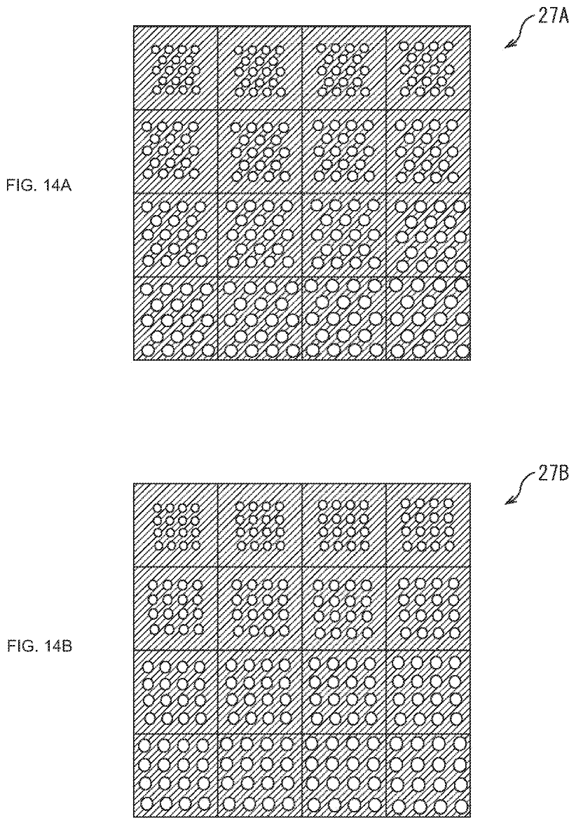

FIG. 13 illustrates a cross-sectional configuration of four pixels 22-1 to 22-4 of the sensor chip 21 using the surface plasmon resonance filter 27. Note that, FIG. 13 illustrates the sensor chip 21 having a configuration in which a wiring layer 44 in which a wire used for driving each pixel 22 is formed is stacked on a front surface side of the semiconductor substrate (opposite side when a surface on which the photodiode 23 is irradiated with light is a rear surface).

As illustrated in FIG. 13, the pixels 22-1 to 22-4 are formed with different hole diameters of fine structures 33-1 to 33-4 formed on the aluminum film 32 of the surface plasmon resonance filter 27. This allows the pixels 22-1 to 22-4 to have different spectral characteristics.

Furthermore, as illustrated in FIG. 12, the surface plasmon resonance filter 27 may arrange the 16 spectral components while changing the period and hole diameters of the fine structures 33 of the 16 (4×4) pixels 22. At that time, as an arrangement of the fine structures 33, a triangular arrangement in which arranging positions of the fine structures 33 in a column direction are alternate for each row may be adopted as a surface plasmon resonance filter 27A illustrated in A of FIG. 14. Alternatively, as in a surface plasmon resonance filter 27B illustrated in B of FIG. 14, a square arrangement in which arranging positions of the fine structures 33 are arranged in a row direction and a column direction may be adopted.

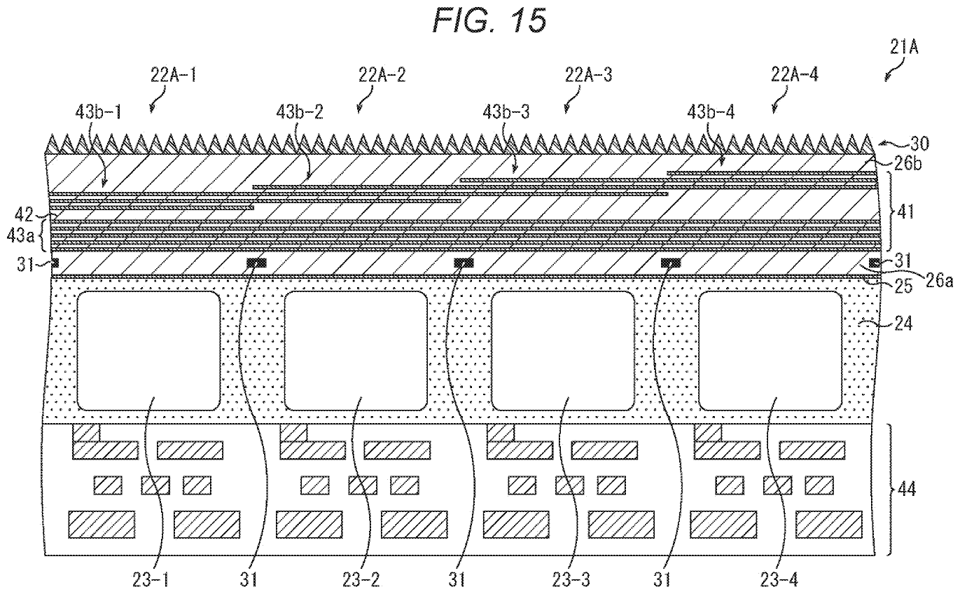

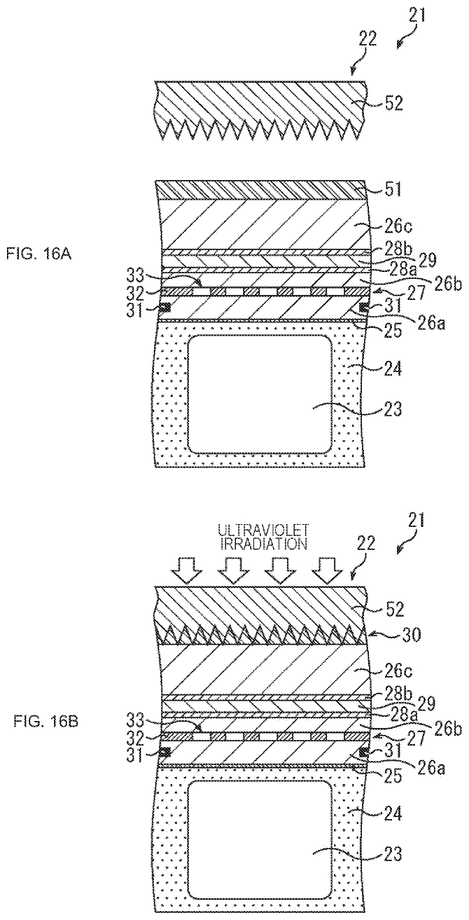

FIG. 15 illustrates a cross-sectional configuration of four pixels 22A-1 to 22A-4 of the sensor chip 21A using the Fabry-Perot resonator 41. Note that, as FIG. 13, FIG. 15 illustrates the sensor chip 21A in which the wiring layer 44 is stacked on a front surface side of the semiconductor substrate 24.

As illustrated in FIG. 15, the pixels 22A-1 to 22A-4 are formed with different thicknesses of the resonator 42 of the Fabry-Perot resonator 41. This allows the pixels 22-1 to 22-4 to have different spectral characteristics.

Note that, by changing the thickness of the resonator 42 in this manner, a step is provided on a surface of the silicon oxide film 26b of the sensor chip 21A for each pixel 22A. For example, in the sensor chip 21A, this step may be flattened by a chemical mechanical polishing (CMP) process or the like, and then the moth-eye structure 30 may be formed on the outermost surface.

<Manufacturing Method of Sensor Chip>

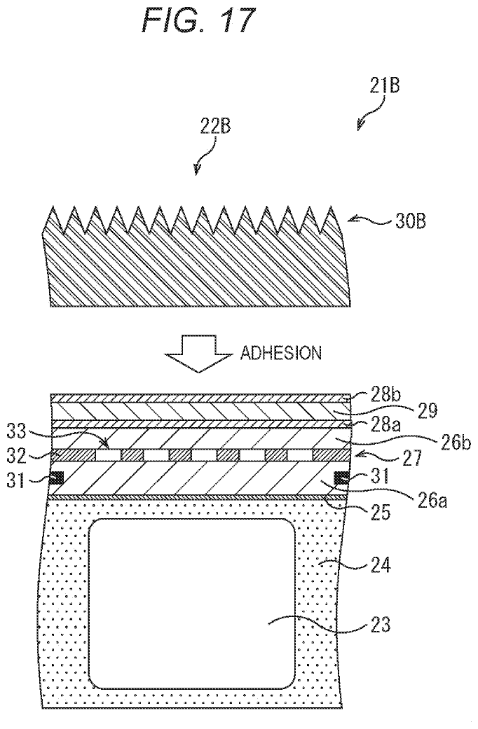

As a manufacturing method of the sensor chip 21, a manufacturing method using a nanoimprinting technology is described with reference to FIG. 16. Note that, the sensor chip 21A in FIG. 6 may also be manufactured by a similar manufacturing method.

In this manufacturing method, a mold 52 which is a mold is prepared in advance. The mold 52 may be formed, for example, by processing a semiconductor substrate by dry etching with a pattern smaller than a wavelength order with a resist by electron beam lithography.

First, as illustrated in A of FIG. 16, an ultraviolet curable resin 51 is applied to a surface of a structure stacked from the antireflection film 25 to the silicon oxide film 26c on the semiconductor substrate 24 by spin coating so as to obtain a uniform thickness. Then, as illustrated in B of FIG. 16, the mold 52 is pressed against the ultraviolet curable resin 51, and the ultraviolet curable resin 51 is irradiated with ultraviolet rays in the pressed state to be cured. Thereafter, when the mold 52 is peeled off, the pattern formed on the mold 52 is transferred to the ultraviolet curable resin 51, and the moth-eye structure 30 is formed.

By such manufacturing method, the sensor chip 21 in which the ripple is reduced as described above having the original spectral characteristic of the surface plasmon resonance filter 27 may be manufactured.

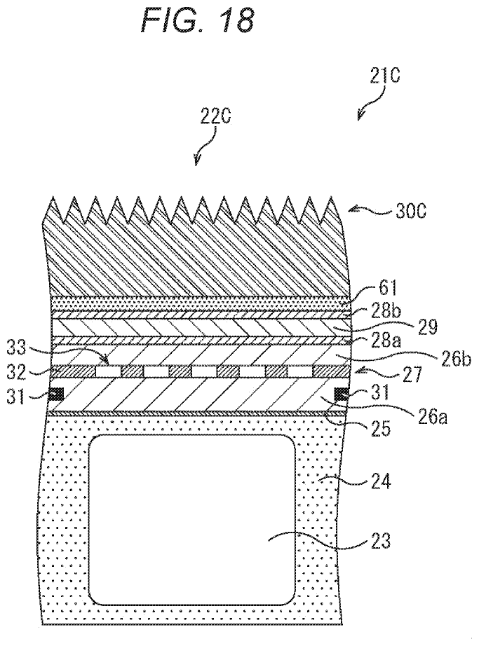

Note that, another manufacturing method of the sensor chip 21 is described with reference to FIG. 17. For example, the sensor chip 21B illustrated in FIG. 17 may be manufactured by forming a moth-eye structure 30B in which a moth-eye is formed on a surface of a resin film having a thickness equivalent to that of the silicon oxide film 26c separate from the structure from the semiconductor substrate 24 to the silicon oxynitride film 28b, and thereafter adhering the moth-eye structure 30B to the silicon oxynitride film 28b.

In the sensor chip 21B manufactured in this manner also, it is possible to provide pixels 22B having different spectral sensitivity characteristics by changing the period and the hole diameters of the fine structures 33 forming the surface plasmon resonance filter 27 for each pixel 22B as illustrated in FIG. 14, for example. Then, the sensor chip 21B may obtain a multi-spectrum by performing signal processing on such a plurality of spectral components, and may appropriately use the same to various applications such as agriculture and living body authentication as described later with reference to FIGS. 20 and 21.

<Third Configuration Example of Sensor Chip>

FIG. 18 illustrates a cross-sectional configuration of a sensor chip 21C of a third configuration example. Note that, in the sensor chip 21C illustrated in FIG. 18, the same reference sign is given to a configuration common to that of the sensor chip 21 in FIG. 3, and the detailed description thereof is not repeated.

As illustrated in FIG. 18, the sensor chip 21C is formed by stacking a stress relaxation resin material film 61 between the silicon oxynitride film 28b and a moth-eye structure 30C. That is, the sensor chip 21C is manufactured by adhering the moth-eye structure 30C to the stress relaxation resin material film 61 after stacking the stress relaxation resin material film 61 on the silicon oxynitride film 28b when manufacturing by the manufacturing method described above with reference to FIG. 17.

For example, when the moth-eye structure 30C including resin is directly adhered to the silicon oxynitride film 28b, there is a concern that the moth-eye structure 30C might be peeled off by dicing when forming a chip. Therefore, in the sensor chip 21C, in order to improve adhesion between the silicon oxynitride film 28b and the moth-eye structure 30C and to relax the stress, for example, the stress relaxation resin material film 61 having a thickness of about 0.35 μm is applied on the silicon oxynitride film 28b.

Therefore, as described above, the sensor chip 21C may prevent peeling-off of the moth-eye structure 30C and further improve reliability.

Furthermore, in the sensor chip 21C having such structure also, for example, it is possible to provide pixels 22C having different spectral sensitivity characteristics by changing the period and the hole diameters of the fine structures 33 forming the surface plasmon resonance filter 27 for each pixel 22C as illustrated in FIG. 14. Then, the sensor chip 21C may obtain a multi-spectrum by performing signal processing on such a plurality of spectral components, and may appropriately use the same to various applications such as agriculture and living body authentication as described later with reference to FIGS. 20 and 21.

<Fourth Configuration Example of Sensor Chip>

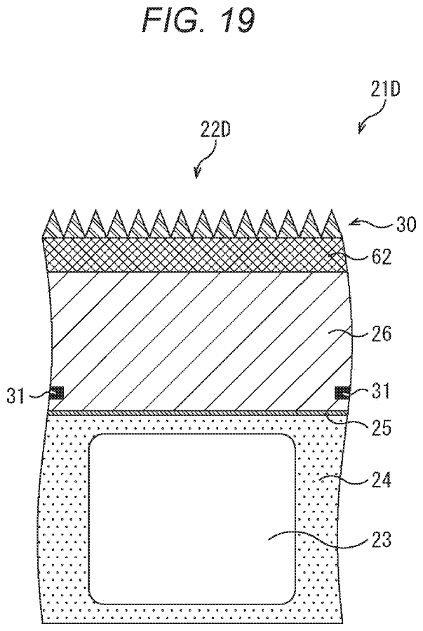

FIG. 19 illustrates a cross-sectional configuration of a sensor chip 21D of a fourth configuration example. Note that, in the sensor chip 21D illustrated in FIG. 19, the same reference sign is given to a configuration common to that of the sensor chip 21 in FIG. 3, and the detailed description thereof is not repeated.

For example, the sensor chip 21D is a CMOS image sensor including an on-chip color filter 62. That is, the sensor chip 21D is formed by stacking the antireflection film 25, the silicon oxide film 26, the on-chip color filter 62, and the moth-eye structure 30 on the semiconductor substrate 24 in which the photodiode 23 is formed for each pixel 22D. Furthermore, on the silicon oxide film 26, the light-shielding film 31 for preventing light leakage between the pixels 22D is formed.

Here, the sensor chip 21D is configured such that, after forming the on-chip color filter 62, an outermost surface thereof is processed to be flat, and the moth-eye structure 30 is arranged on the flat surface.

Since the sensor chip 21D having such a configuration may suppress reflection on a surface on which light is incident, it is possible to improve sensitivity of the pixel 22D and suppress occurrence of flare due to reflected light.

<Usage Example of Sensor Chip>

An application which uses the sensor chip 21 (including the sensor chips 21A to 21C) is described with reference to FIGS. 20 and 21.

For example, the sensor chip 21 may be used in a spectral device which performs multi-spectroscopy or hyperspectral spectroscopy for measuring a normalized difference vegetation index (NDVI) in agriculture, plant growth and the like. FIG. 20 illustrates a spectral characteristic of reflectance depending on a plant state.

As illustrated in FIG. 20, it is understood that the reflectance significantly changes depending on a vegetation state in a wavelength range of 600 to 800 nm, so that the reflectance is different among healthy plants, weak plants, and dead plants. For example, this reflectance is mainly from plant leaves. Then, from these results, it is possible to detect the vegetation state of plants by obtaining a multispectral characteristic of two or more wavelengths at least across a wavelength range of 600 to 800 nm or in the wavelength range of 600 to 800 nm.

For example, it is possible to detect the vegetation state from a relationship between two signal values by using the sensor chip 21 which detects a wavelength range of 600 to 700 nm and the sensor chip 21 which detects a wavelength range of 700 to 800 nm. Alternatively, it is possible to detect the vegetation state from a relationship between two signal values by using the sensor chip 21 which detects a wavelength range of 400 to 600 nm and the sensor chip 21 which detects a wavelength range of 800 to 1000 nm. Moreover, in order to improve detection accuracy, it is possible to use three or more sensor chips 21 to detect three or more wavelength ranges, and detect the vegetation state from a relationship of the signal values.

Therefore, it is possible to mount the sensor chip 21 capable of detecting such wavelength range on, for example, a small unmanned aerial vehicle (so-called drone), thereby observing a growing state of agricultural crops from the sky to promote cultivation of crops.

Furthermore, the sensor chip 21 may be used, for example, in a spectral device which performs multi-spectroscopy or hyperspectral spectroscopy to perform spectroscopy into a plurality of spectral components in multiple bands of three primary colors of light or more in order to measure reflectance of human skin in living body authentication. FIG. 21 illustrates a spectral characteristic of the reflectance of the human skin.

As illustrated in FIG. 21, it is understood that the reflectance significantly changes in a wavelength range of 450 to 650 nm. From the change, it is possible to authenticate whether an object is the human skin.

For example, by using the three sensor chips 21 to detect three spectral components of wavelengths of 450 nm, 550 nm, and 650 nm, it is possible to authenticate whether the object is the human skin. For example, in a case where the object is a material other than the human skin, the spectral characteristic of the reflectance changes, so that this may be distinguished from the human skin.

Therefore, by mounting the sensor chip 21 capable of detecting such wavelength range on, for example, a living body authentication device, this may be applied to prevention of forgery of a face, fingerprint, iris and the like, and more accurate living body authentication may be performed.

FIG. 22 is a block diagram illustrating a configuration example of an imaging element to which a stacked structure similar to that of the above-described sensor chips 21 to 21C is applied.

In FIG. 22, an imaging element 71 is a CMOS solid-state imaging element, and includes a pixel array 72, a row scanning circuit 73, a phase locked loop (PLL) 74, a digital analog converter (DAC) 75, a column analog digital converter (ADC) circuit 76, a column scanning circuit 77, and a sense amplifier 78.

The pixel array 72 includes a plurality of pixels 81 arranged two-dimensionally, and the pixel 81 is formed by a stacked structure similar to that of the pixels 22, 22A and the like described above. Furthermore, the pixels 81 are arranged at intersections of horizontal signal lines H connected to the row scanning circuit 73 and vertical signal lines V connected to the column ADC circuit 76, and includes photodiodes for performing photoelectric conversion and several types of transistors for reading accumulated signals.

That is, the pixel 81 includes a photodiode 82, a transfer transistor 83, a floating diffusion 84, an amplification transistor 85, a selection transistor 86, and a reset transistor 87 as illustrated in an enlarged manner on a right side of FIG. 22.

Charges accumulated in the photodiode 82 are transferred to the floating diffusion 84 via the transfer transistor 83. The floating diffusion 84 is connected to a gate of the amplification transistor 85. When the pixel 81 becomes a signal reading target, the selection transistor 86 is turned on from the row scanning circuit 73 via the horizontal signal line H, and a signal of the selected pixel 81 is read out to the vertical signal line V as a pixel signal corresponding to an accumulated charge amount of the charges accumulated in the photodiode 82 by source follower driving the amplification transistor 85. Furthermore, the pixel signal is reset by turning on the reset transistor 87.

The row scanning circuit 73 sequentially outputs drive signals for driving (transferring, selecting, resetting and the like) the pixels 81 of the pixel array 72 for each row. The PLL 74 generates and outputs a clock signal of a predetermined frequency necessary for driving each block in the imaging element 71 on the basis of an externally supplied clock signal. The DAC 75 generates and outputs a ramp signal having a shape (substantially saw-like shape) in which a voltage drops from a predetermined voltage value at a constant inclination and then returns to the predetermined voltage value.

The column ADC circuit 76 includes comparators 91 and counters 92 as many as the columns of the pixels 81 of the pixel array 72, and extracts a signal level from the pixel signal output from the pixel 81 by correlated double sampling (CDS) operation to output pixel data. That is, the comparator 91 compares the ramp signal supplied from the DAC 75 with the pixel signal (luminance value) output from the pixel 81, and supplies a comparison result signal obtained as a result to the counter 92. Then, the counter 92 counts counter clock signals of a predetermined frequency in accordance with the comparison result signal output from the comparator 91, thereby A/D converting the pixel signal.

The column scanning circuit 77 sequentially supplies the counter 92 of the column ADC circuit 76 with signals for outputting the pixel data at a predetermined timing. The sense amplifier 78 amplifies the pixel data supplied from the column ADC circuit 76 and outputs the same to the outside of the imaging element 71.

Since the image data output from the imaging element 71 is intensity information of each color of RGB in a mosaic pattern, respective color information in all pixel positions is interpolated by demosaic processing from the intensity information of adjacent different color pixels in respective pixel positions by a signal processing circuit and the like on a subsequent stage. In addition, data processing such as white balance, gamma correction, edge enhancement, and image compression is performed on the image data. Note that, in a case where the imaging element 71 is a system-on-chip type image sensor on which an image processor is mounted, the processing may also be performed on the same chip. In this case, the imaging element 71 may output image data compressed by a joint photographic experts group (JPEG) method, a moving picture experts group (MPEG) method and the like, in addition to raw image data.

The imaging element 71 configured in this manner may have more excellent spectral characteristic by adopting the pixel 81 having the moth-eye structure 30 on the outermost surface above the surface plasmon resonance filter 27 or the Fabry-Perot resonator 41 as described above.

<Configuration Example of Electronic Device>

The above-described imaging element 71 may be applied to various electronic devices such as an imaging system such as a digital still camera and a digital video camera, a mobile phone having an imaging function, or another device having an imaging function, for example.

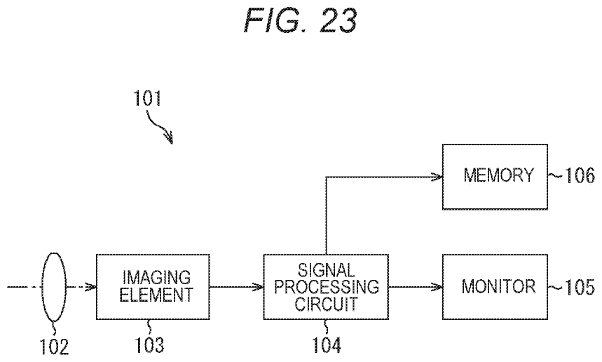

FIG. 23 is a block diagram illustrating a configuration example of an imaging device mounted on an electronic device.

As illustrated in FIG. 23, an imaging device 101 provided with an optical system 102, an imaging element 103, a signal processing circuit 104, a monitor 105, and a memory 106 may take a still image and a moving image.

The optical system 102 including one or a plurality of lenses guides image light from an object (incident light) to the imaging element 103 to form an image on a light-receiving surface (sensor unit) of the imaging element 103.

The sensor chip 21D described above is applied as the imaging element 103. Electrons are accumulated in the imaging element 103 for a certain period in accordance with the image formed on the light-receiving surface via the optical system 102. Then, a signal corresponding to the electrons accumulated in the imaging element 103 is supplied to the signal processing circuit 104.

The signal processing circuit 104 performs various types of signal processing on the pixel signal output from the imaging element 103. An image (image data) obtained by the signal processing applied by the signal processing circuit 104 is supplied to the monitor 105 to be displayed or supplied to the memory 106 to be stored (recorded).

In the imaging device 101 configured in this manner, by applying the above-described imaging element 71, it is possible to obtain a narrower multispectral image. Furthermore, by applying the sensor chip 21D to the imaging device 101, for example, it is possible to take a higher-quality image with high sensitivity while suppressing occurrence of flare due to reflected light.

<Usage Example of Image Sensor>

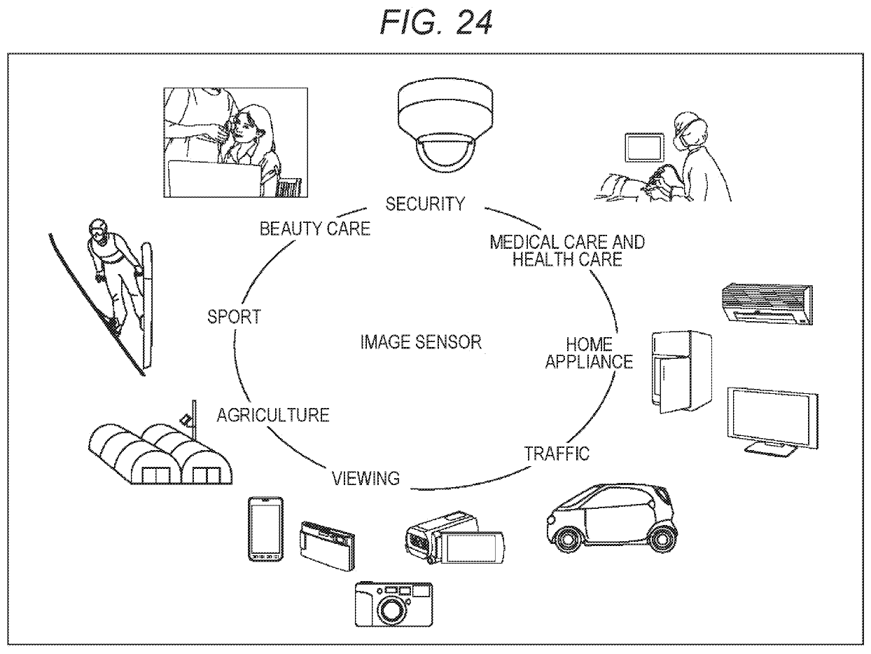

FIG. 24 is a view illustrating a usage example of using the above-described image sensor (sensor chip 21).

The above-described image sensor may be used in various cases in which light such as visible light, infrared light, ultraviolet light, and X-ray is sensed as hereinafter described, for example.
A device which takes an image to be used for viewing such as a digital camera and a portable device with a camera function
A device for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device for home appliance such as a television, a refrigerator, and an air conditioner which takes an image of a user's gesture and performs device operation according to the gesture
A device for medical and health care use such as an endoscope and a device which performs angiography by receiving infrared light
A device for security use such as a security monitoring camera and an individual authentication camera
A device for beauty care such as a skin condition measuring device which takes an image of skin and a microscope which takes an image of scalp
A device for sporting use such as an action camera and a wearable camera for sporting use and the like
A device for agricultural use such as a camera for monitoring land and crop states

<Configuration Example of Stacked Solid-State Imaging Device to Which Technology According to Present Disclosure Is Applicable>

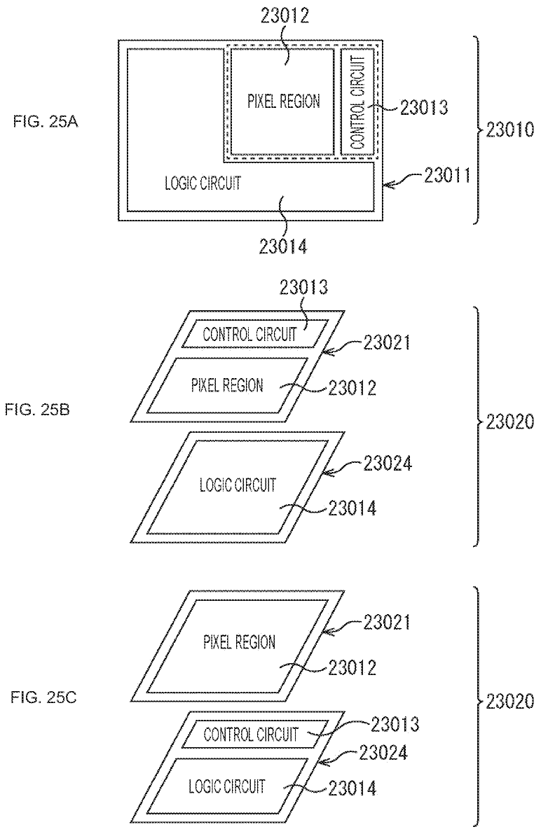

FIG. 25 is a view illustrating an outline of a configuration example of a stacked solid-state imaging device to which the technology according to the present disclosure is applicable.

A of FIG. 25 illustrates a schematic configuration example of a non-stacked solid-state imaging device. A solid-state imaging device 23010 includes one die (semiconductor substrate) 23011 as illustrated in A of FIG. 25. The die 23011 is equipped with a pixel region 23012 in which pixels are arranged into an array, a control circuit 23013 which drives the pixels and performs other various controls, and a logic circuit 23014 for performing signal processing.

B and C of FIG. 25 illustrate schematic configuration examples of a stacked solid-state imaging device. As illustrated in B and C of FIG. 25, a solid-state imaging device 23020 is configured as one semiconductor chip by stacking two dies of a sensor die 23021 and a logic die 23024 and electrically connecting them.

In B of FIG. 25, the sensor die 23021 is equipped with a pixel region 23012 and a control circuit 23013, and the logic die 23024 is equipped with a logic circuit 23014 including a signal processing circuit for performing signal processing.

In C of FIG. 25, the sensor die 23021 is equipped with the pixel region 23012, and the logic die 23024 is equipped with the control circuit 23013 and the logic circuit 23014.

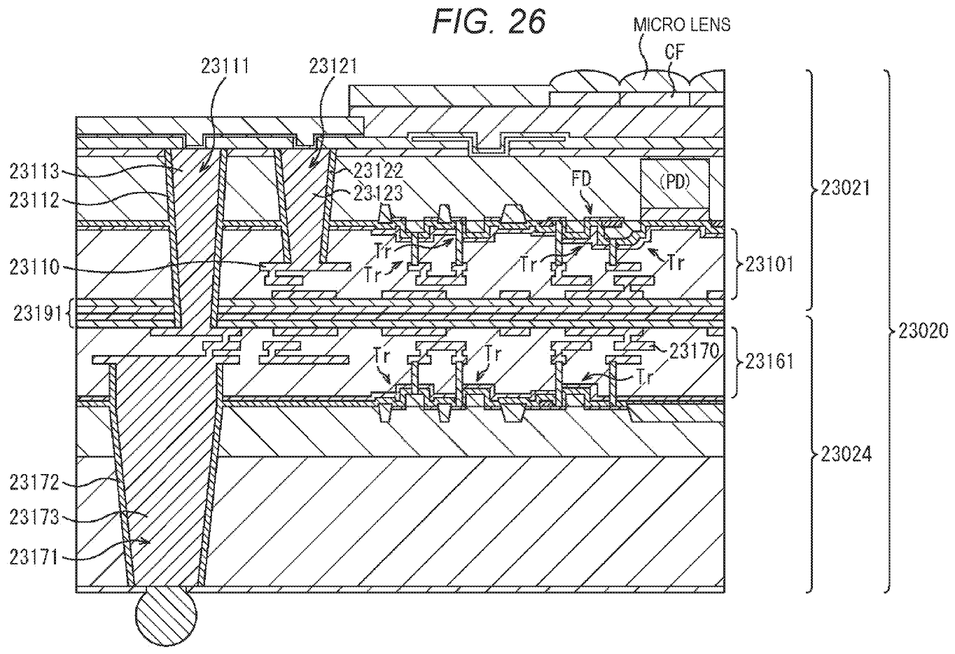

FIG. 26 is a cross-sectional view illustrating a first configuration example of the stacked solid-state imaging device 23020.

On the sensor die 23021, a photodiode (PD), a floating diffusion (FD), a Tr (MOS FET) which form a pixel serving as the pixel region 23012, a Tr serving as the control circuit 23013 and the like are formed. Moreover, a wiring layer 23101 including a plurality of (in this example, three) layers of wires 23110 is formed on the sensor die 23021. Note that, (Tr which serves as) the control circuit 23013 may be formed not on the sensor die 23021 but on the logic die 23024.

On the logic die 23024, Tr forming the logic circuit 23014 is formed. Moreover, a wiring layer 23161 including a plurality of (in this example, three) layers of wires 23170 is formed on the logic die 23024. Furthermore, in the logic die 23024, a connection hole 23171 having an insulating film 23172 formed on an inner wall surface thereof is formed, and a connection conductor 23173 connected to the wire 23170 and the like is embedded in the connection hole 23171.

The sensor die 23021 and the logic die 23024 are bonded to each other so that the wiring layers 23101 and 23161 face each other, thereby forming the stacked solid-state imaging device 23020 in which the sensor die 23021 and the logic die 23024 are stacked. A film 23191 such as a protective film is formed on a surface on which the sensor die 23021 and the logic die 23024 are bonded to each other.

In the sensor die 23021, a connection hole 23111 is formed which penetrates the sensor die 23021 from a back surface side (side on which light is incident on PD) (upper side) of the sensor die 23021 to reach the wire 23170 in an uppermost layer of the logic die 23024. Moreover, a connection hole 23121 is formed in the vicinity of the connection hole 23111 in the sensor die 23021 so as to reach the first-layer wire 23110 from the back surface side of the sensor die 23021. An insulating film 23112 is formed on an inner wall surface of the connection hole 23111, and an insulating film 23122 is formed on an inner wall surface of the connection hole 23121. Then, connection conductors 23113 and 23123 are embedded in the connection holes 23111 and 23121, respectively. The connection conductor 23113 and the connection conductor 23123 are electrically connected on the back surface side of the sensor die 23021, therefore the sensor die 23021 and the logic die 23024 are electrically connected through the wiring layer 23101, the connection hole 23121, the connection hole 23111, and the wiring layer 23161.

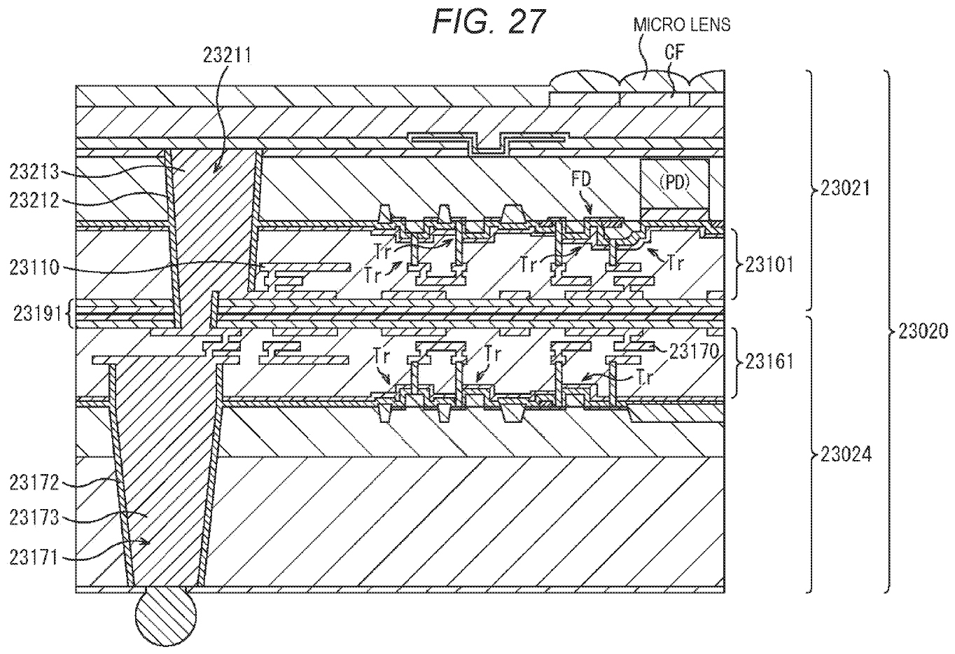

FIG. 27 is a cross-sectional view illustrating a second configuration example of the stacked solid-state imaging device 23020.

In the second configuration example of the solid-state imaging device 23020, ((the wire 23110 of) the wiring layer 23101 of) the sensor die 23021 and ((the wire 23170 of) the wiring layer 23161 of) the logic die 23024 are electrically connected to each other through one connection hole 23211 formed in the sensor die 23021.

That is, in FIG. 27, the connection hole 23211 is formed so as to penetrate the sensor die 23021 from the back surface side of the sensor die 23021 to reach the wire 23170 in the uppermost layer of the logic die 23024 and reach the wire 23110 in the uppermost layer of the sensor die 23021. An insulating film 23212 is formed on an inner wall surface of the connection hole 23211, and a connection conductor 23213 is embedded in the connection hole 23211. In FIG. 26 described above, the sensor die 23021 and the logic die 23024 are electrically connected to each other by the two connection holes 23111 and 23121, but in FIG. 27, the sensor die 23021 and the logic die 23024 are electrically connected to each other by one connection hole 23211.

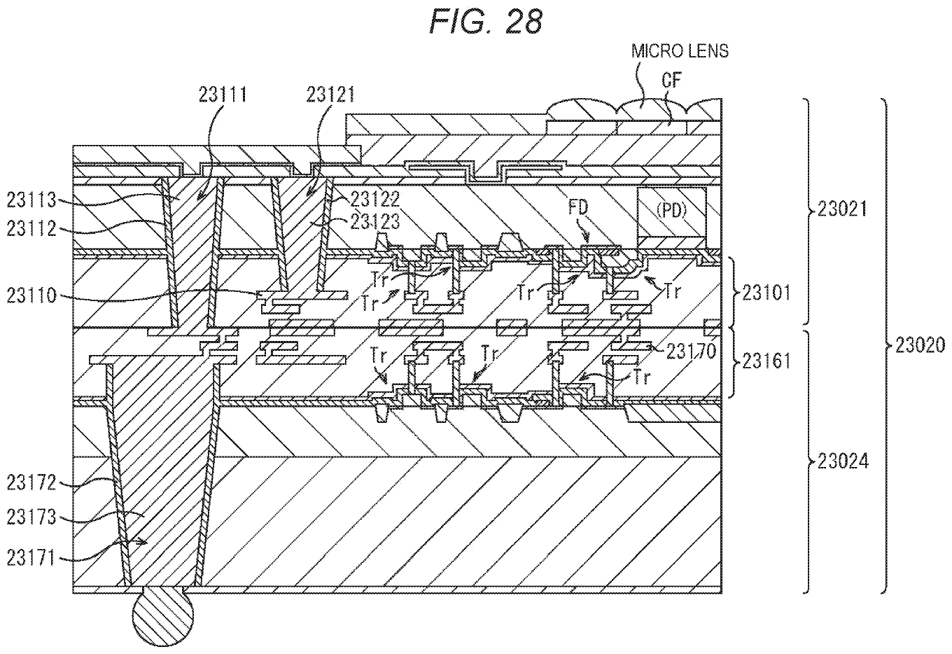

FIG. 28 is a cross-sectional view illustrating a third configuration example of the stacked solid-state imaging device 23020.

The solid-state imaging device 23020 in FIG. 28 is different from that in FIG. 26 in which the film 23191 such as the protective film is formed on the surface on which the sensor die 23021 and the logic die 23024 are bonded to each other in that the film 23191 such as the protective film is not formed on the surface on which the sensor die 23021 and the logic die 23024 are bonded to each other.

The solid-state imaging device 23020 in FIG. 28 is formed by overlapping the sensor die 23021 and the logic die 23024 such that the wires 23110 and 23170 are brought into direct contact with each other, and heating them while applying a required weight to directly join the wires 23110 and 23170.

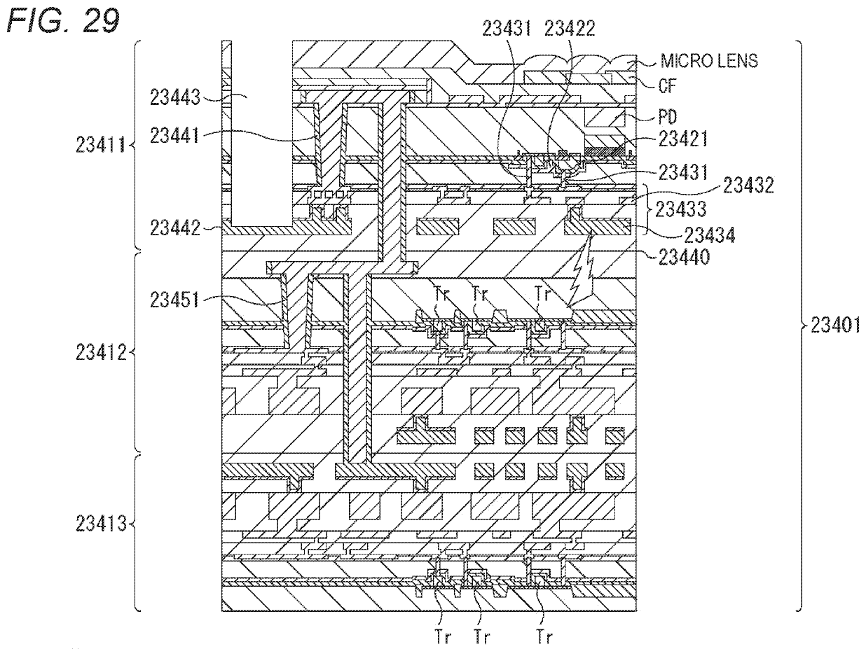

FIG. 29 is a cross-sectional view illustrating another configuration example of a stacked solid-state imaging device to which the technology according to the present disclosure is applicable.

In FIG. 29, a solid-state imaging device 23401 has a three-layer stacked structure in which three dies including a sensor die 23411, a logic die 23412, and a memory die 23413 are stacked.

The memory die 23413 includes, for example, a memory circuit which stores data temporarily required in signal processing performed by the logic die 23412.

In FIG. 29, the logic die 23412 and the memory die 23413 are stacked in this order under the sensor die 23411, but the logic die 23412 and the memory die 23413 may be stacked under the sensor die 23411 in reverse order, that is, in order of the memory die 23413 and the logic die 23412.

Note that, in FIG. 29, in the sensor die 23411, a PD serving as a photoelectric conversion unit of a pixel and a source/drain region of the pixel Tr are formed.

A gate electrode is formed around the PD with a gate insulating film interposed therebetween, and a pixel Tr 23421 and a pixel Tr 23422 are formed by the gate electrode and a pair of source/drain regions.

The pixel Tr 23421 adjacent to the PD is a transfer Tr, and one of the pair of source/drain regions forming the pixel Tr 23421 is a FD.

Furthermore, an interlayer insulating film is formed in the sensor die 23411, and a connection hole is formed on the interlayer insulating film. In the connection hole, a connection conductor 23431 connected to the pixel Tr 23421 and the pixel Tr 23422 is formed.

Moreover, a wiring layer 23433 including a plurality of layers of wires 23432 connected to each connection conductor 23431 is formed in the sensor die 23411.

Furthermore, an aluminum pad 23434 serving as an electrode for external connection is formed in a lowermost layer of the wiring layer 23433 of the sensor die 23411. That is, in the sensor die 23411, the aluminum pad 23434 is formed in a position closer to a bonding surface 23440 with the logic die 23412 than the wire 23432. The aluminum pad 23434 is used as one end of a wire regarding external input/output of a signal.

Moreover, a contact 23441 used for electrical connection to the logic die 23412 is formed in the sensor die 23411. The contact 23441 is connected to a contact 23451 of the logic die 23412 and also to an aluminum pad 23442 of the sensor die 23411.

Then, a pad hole 23443 is formed in the sensor die 23411 so as to reach the aluminum pad 23442 from the back surface side (upper side) of the sensor die 23411.

The technology according to the present disclosure may be applied to the stacked solid-state imaging device as described above. That is, as a color filter (CF) and a surface structure, it is possible to apply the configuration including the moth-eye structure 30 on the outermost surface above the surface plasmon resonance filter 27 or the Fabry-Perot resonator 41 as described above, thereby providing an excellent spectral characteristic.

<Application Example to Endoscopic Surgery System>

The technology according to the present disclosure (present technology) is applicable to various products. For example, the technology according to the present disclosure may be applied to an endoscopic surgery system.

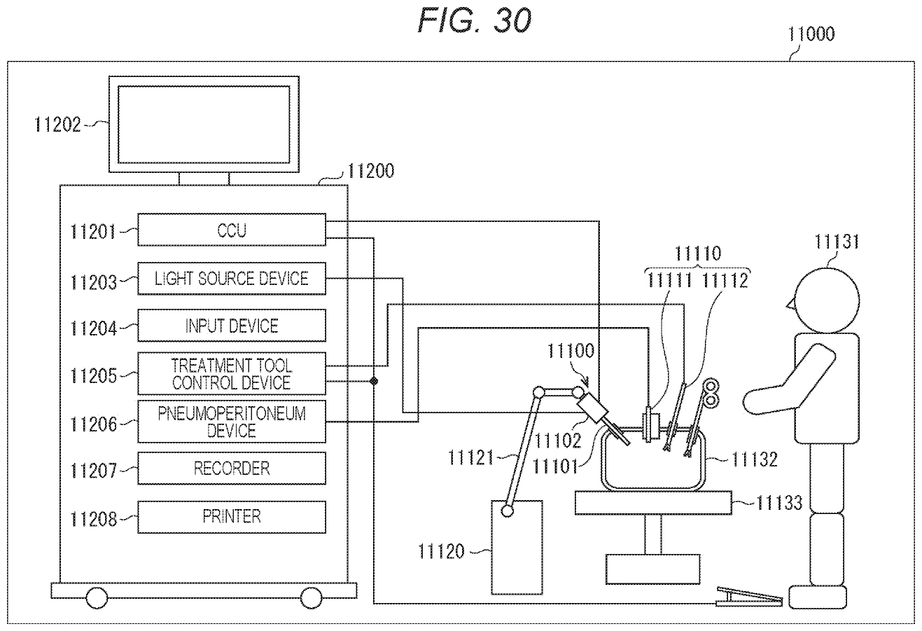

FIG. 30 is a view illustrating an example of a schematic configuration of the endoscopic surgery system to which the technology according to the present disclosure (present technology) may be applied.

FIG. 30 illustrates a state in which an operator (surgeon) 11131 performs surgery on a patient 11132 on a patient bed 11133 by using an endoscopic surgery system 11000. As illustrated, the endoscopic surgery system 11000 includes an endoscope 11100, other surgical tools 11110 such as a pneumoperitoneum tube 11111 and an energy treatment tool 11112, a support arm device 11120 which supports the endoscope 11100, and a cart 11200 on which various devices for endoscopic surgery are mounted.

The endoscope 11100 includes a lens tube 11101 a region of a predetermined length from a distal end of which is inserted into a body cavity of the patient 11132 and a camera head 11102 connected to a proximal end of the lens tube 11101. In the illustrated example, the endoscope 11100 configured as a so-called rigid scope having a rigid lens tube 11101 is illustrated, but the endoscope 11100 may also be configured as a so-called flexible scope having a flexible lens tube.

At the distal end of the lens tube 11101, an opening into which an objective lens is fitted is provided. A light source device 11203 is connected to the endoscope 11100 and light generated by the light source device 11203 is guided to the distal end of the lens tube by a light guide extending inside the lens tube 11101, and applied to an observation target in the body cavity of the patient 11132 via the objective lens. Note that, the endoscope 11100 may be a forward-viewing endoscope, an oblique-viewing endoscope, or a side-viewing endoscope.

An optical system and an imaging element are provided inside the camera head 11102, and reflected light (observation light) from the observation target is condensed on the imaging element by the optical system. The observation light is photoelectrically converted by the imaging element, and an electric signal corresponding to the observation light, that is, am image signal corresponding to an observation image is generated. The image signal is transmitted as RAW data to a camera control unit (CCU) 11201.

The CCU 11201 is configured by a central processing unit (CPU), a graphics processing unit (GPU) and the like, and comprehensively controls operation of the endoscope 11100 and the display device 11202. Moreover, the CCU 11201 receives the image signal from the camera head 11102 and applies various types of image processing for displaying an image based on the image signal, for example, development processing (demosaic processing) and the like on the image signal.

The display device 11202 displays the image based on the image signal subjected to the image processing by the CCU 11201 under the control of the CCU 11201.

The light source device 11203 includes a light source such as, for example, a light emitting diode (LED), and supplies the endoscope 11100 with irradiation light for imaging a surgical site and the like.

An input device 11204 is an input interface to the endoscopic surgery system 11000. A user may input various types of information and instructions to the endoscopic surgery system 11000 via the input device 11204. For example, the user inputs an instruction and the like to change an imaging condition (type of irradiation light, magnification, focal length and the like) by the endoscope 11100.

A treatment tool control device 11205 controls drive of the energy treatment tool 11112 for tissue cauterization, incision, blood vessel sealing or the like. A pneumoperitoneum device 11206 injects gas into the body cavity via the pneumoperitoneum tube 11111 to inflate the body cavity of the patient 11132 for the purpose of securing a visual field by the endoscope 11100 and securing a working space of the operator. A recorder 11207 is a device capable of recording various types of information regarding surgery. A printer 11208 is a device capable of printing various types of information regarding surgery in various formats such as text, image, or graph.

Note that, the light source device 11203 which supplies the irradiation light for imaging the surgical site to the endoscope 11100 may include, for example, an LED, a laser light source, or a white light source obtained by combining them. Since output intensity and output timing of each color (each wavelength) may be controlled with a high degree of accuracy in a case where the white light source is formed by the combination of RGB laser light sources, the light source device 11203 may adjust white balance of the taken image. Furthermore, in this case, by irradiating the observation target with the laser light from each of the RGB laser light sources in time division manner and controlling the drive of the imaging element of the camera head 11102 in synchronism with the irradiation timing, it is possible to take images corresponding to RGB in time division manner. According to this method, a color image may be obtained without providing a color filter in the imaging element.

Furthermore, drive of the light source device 11203 may be controlled such that the intensity of light to be output is changed every predetermined time. By controlling drive of the imaging element of the camera head 11102 in synchronization with the timing of the change of the light intensity to obtain images in a time division manner and combining the images, an image of a high dynamic range without so-called black defect and halation may be generated.

Furthermore, the light source device 11203 may be configured to be able to supply light of a predetermined wavelength band corresponding to special light observation. In the special light observation, for example, by applying light of a narrower band than that of the irradiation light (in other words, white light) at ordinary observation by utilizing wavelength dependency of absorption of light in the body tissue, so-called narrow band imaging is performed in which predetermined tissue such as the blood vessel in the mucosal surface layer is imaged with high contrast. Alternatively, in the special light observation, fluorescent observation for obtaining an image by fluorescence generated by irradiation of excitation light may be performed. In the fluorescent observation, it is possible, for example, to irradiate the body tissue with excitation light to observe fluorescence from the body tissue (autonomous fluorescent observation) or to locally inject a reagent such as indocyanine green (ICG) to the body tissue and irradiate the body tissue with excitation light corresponding to a fluorescent wavelength of the reagent, thereby obtaining a fluorescent image. The light source device 11203 may be configured to be able to supply the narrow band light and/or excitation light corresponding to such special light observation.

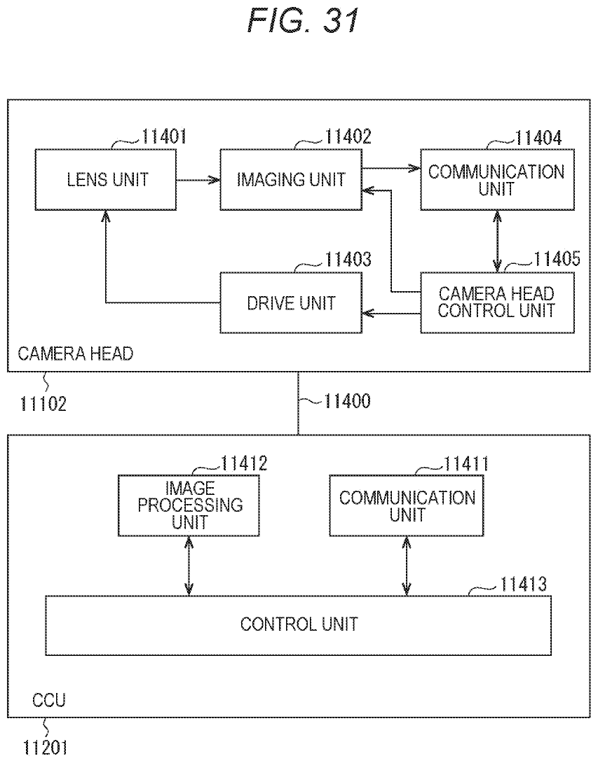

FIG. 31 is a block diagram illustrating an example of functional configurations of the camera head 11102 and the CCU 11201 illustrated in FIG. 30.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are connected to each other so as to be able to communicate by a transmission cable 11400.

The lens unit 11401 is an optical system provided at a connection to the lens tube 11101. The observation light taken in from the distal end of the lens tube 11101 is guided to the camera head 11102 and is incident on the lens unit 11401. The lens unit 11401 is configured by combining a plurality of lenses including a zoom lens and a focus lens.

The imaging unit 11402 includes an imaging element. The imaging element forming the imaging unit 11402 may be one (a so-called single plate type) or a plurality of imaging elements (so-called multiple plate type). In a case where the imaging unit 11402 is of the multiple plate type, for example, the image signals corresponding to RGB may be generated by the respective imaging elements, and a color image may be obtained by combining them. Alternatively, the imaging unit 11402 may include a pair of imaging elements for obtaining right-eye and left-eye image signals corresponding to three-dimensional (3D) display. By the 3D display, the operator 11131 may grasp a depth of the living tissue in the surgical site more accurately. Note that, in a case where the imaging unit 11402 is of the multiple plate type, a plurality of systems of lens units 11401 may be provided so as to correspond to the respective imaging elements.

Furthermore, the imaging unit 11402 is not necessarily provided on the camera head 11102. For example, the imaging unit 11402 may be provided inside the lens tube 11101 immediately after the objective lens.

The drive unit 11403 includes an actuator and moves the zoom lens and the focus lens of the lens unit 11401 by a predetermined distance along an optical axis under the control of the camera head control unit 11405. Therefore, the magnification and focal point of the image taken by the imaging unit 11402 may be appropriately adjusted.

The communication unit 11404 includes a communication device for transmitting and receiving various types of information to and from the CCU 11201. The communication unit 11404 transmits the image signal obtained from the imaging unit 11402 as the RAW data to the CCU 11201 via the transmission cable 11400.

Furthermore, the communication unit 11404 receives a control signal for controlling drive of the camera head 11102 from the CCU 11201 and supplies the same to the camera head control unit 11405. The control signal includes, for example, information regarding imaging conditions such as information specifying a frame rate of the taken image, information specifying an exposure value at the time of imaging, and/or information specifying the magnification and focal point of the taken image.

Note that, the imaging conditions such as the above-described frame rate, exposure value, magnification, and focal point may be appropriately specified by the user or automatically set by the control unit 11413 of the CCU 11201 on the basis of the obtained image signal. In the latter case, a so-called auto exposure (AE) function, an auto focus (AF) function, and an auto white balance (AWB) function are included in the endoscope 11100.

The camera head control unit 11405 controls the drive of the camera head 11102 on the basis of the control signal from the CCU 11201 received via the communication unit 11404.

The communication unit 11411 includes a communication device for transmitting and receiving various types of information to and from the camera head 11102. The communication unit 11411 receives the image signal transmitted from the camera head 11102 via the transmission cable 11400.

Furthermore, the communication unit 11411 transmits the control signal for controlling the drive of the camera head 11102 to the camera head 11102. The image signal and the control signal may be transmitted by electric communication, optical communication and the like.

The image processing unit 11412 performs various types of image processing on the image signal which is the RAW data transmitted from the camera head 11102.

The control unit 11413 performs various types of control regarding imaging of the surgical site and the like by the endoscope 11100 and display of the taken image obtained by imaging the surgical site and the like. For example, the control unit 11413 generates the control signal for controlling the drive of the camera head 11102.

Furthermore, the control unit 11413 allows the display device 11202 to display the taken image of the surgical site and the like on the basis of the image signal subjected to the image processing by the image processing unit 11412. At that time, the control unit 11413 may recognize various objects in the taken image using various image recognition technologies. For example, the control unit 11413 may detect a shape, a color and the like of an edge of the object included in the taken image, thereby recognizing the surgical tool such as forceps, the specific living-body site, bleeding, mist when using the energy treatment tool 11112 and the like. When allowing the display device 11202 to display the taken image, the control unit 11413 may superimpose to display various types of surgery support information on the image of the surgical site using a recognition result. The surgery support information is superimposed to be displayed, and presented to the operator 11131, so that it becomes possible to reduce a burden on the operator 11131 and enable the operator 11131 to reliably proceed with surgery.

The transmission cable 11400 connecting the camera head 11102 and the CCU 11201 is an electric signal cable corresponding to communication of electric signals, an optical fiber compatible with optical communication, or a composite cable thereof.

Here, in the illustrated example, the communication is performed by wire using the transmission cable 11400, but the communication between the camera head 11102 and the CCU 11201 may be performed wirelessly.

An example of the endoscopic surgery system to which the technology according to the present disclosure may be applied is described above. The technology according to the present disclosure may be applied to the endoscope 11100, (the imaging unit 11402 of) the camera head 11102 and the like, for example, out of the configurations described above. Then, by applying the technology according to the present disclosure, it is possible to take a higher-quality image with high sensitivity while suppressing occurrence of flare due to reflected light.

Note that, the endoscopic surgery system is herein described as an example, but in addition to this, the technology according to the present disclosure may also be applied to a microscopic surgery system and the like, for example.

<Application Example to Mobile Body>

The technology according to the present disclosure (present technology) is applicable to various products. For example, the technology according to the present disclosure may also be realized as a device mounted on any type of mobile body such as an automobile, an electric automobile, a hybrid electric automobile, a motorcycle, a bicycle, a personal mobility, an airplane, a drone, a ship, and a robot.

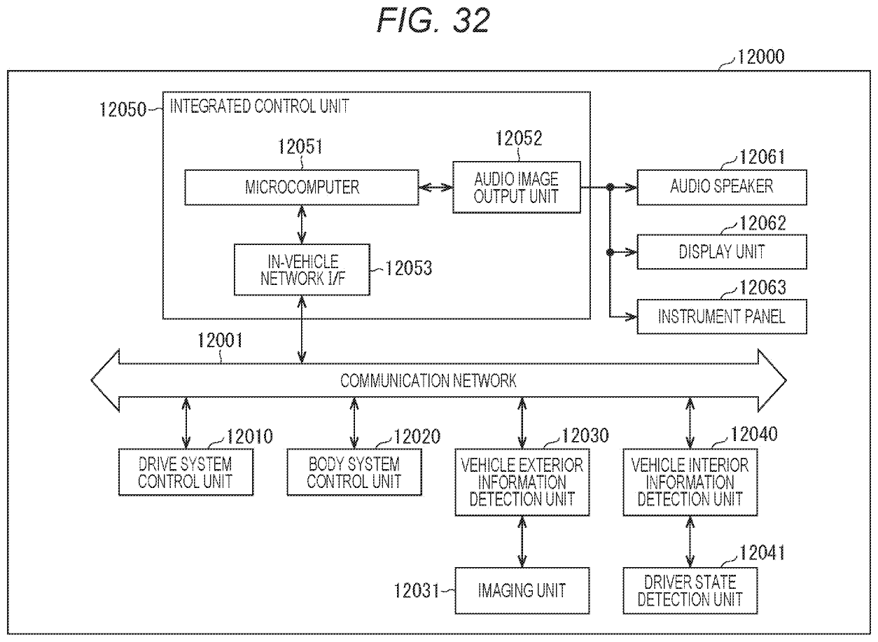

FIG. 32 is a block diagram illustrating a schematic configuration example of a vehicle control system which is an example of a mobile body control system to which the technology according to the present disclosure may be applied.

A vehicle control system 12000 is provided with a plurality of electronic control units connected to one another via a communication network 12001. In the example illustrated in FIG. 32, the vehicle control system 12000 is provided with a drive system control unit 12010, a body system control unit 12020, a vehicle exterior information detection unit 12030, a vehicle interior information detection unit 12040, and an integrated control unit 12050. Furthermore, a microcomputer 12051, an audio image output unit 12052, and an in-vehicle network interface (I/F) 12053 are illustrated as functional configurations of the integrated control unit 12050.

The drive system control unit 12010 controls operation of devices related to a drive system of a vehicle according to various programs. For example, the drive system control unit 12010 serves as a control device of a driving force generating device for generating driving force of the vehicle such as an internal combustion engine or a driving motor, a driving force transmitting mechanism for transmitting the driving force to wheels, a steering mechanism for adjusting a rudder angle of the vehicle, a braking device for generating braking force of the vehicle and the like.

The body system control unit 12020 controls operation of various devices mounted on a vehicle body in accordance with the various programs. For example, the body system control unit 12020 serves as a control device of a keyless entry system, a smart key system, a power window device, or various lights such as a head light, a backing light, a brake light, a blinker, or a fog light. In this case, a radio wave transmitted from a portable device that substitutes for a key or signals of various switches may be input to the body system control unit 12020. The body system control unit 12020 receives an input of the radio wave or signals and controls a door lock device, a power window device, the lights and the like of the vehicle.

The vehicle exterior information detection unit 12030 detects information outside the vehicle on which the vehicle control system 12000 is mounted. For example, an imaging unit 12031 is connected to the vehicle exterior information detection unit 12030. The vehicle exterior information detection unit 12030 allows the imaging unit 12031 to take an image of the exterior of the vehicle and receives the taken image. The vehicle exterior information detection unit 12030 may perform detection processing of objects such as a person, a vehicle, an obstacle, a sign, or a character on a road surface or distance detection processing on the basis of the received image.

The imaging unit 12031 is an optical sensor which receives light and outputs an electric signal corresponding to an amount of the received light. The imaging unit 12031 may output the electric signal as the image or output the same as ranging information. Furthermore, the light received by the imaging unit 12031 may be visible light or invisible light such as infrared light.

The vehicle interior information detection unit 12040 detects information in the vehicle. The vehicle interior information detection unit 12040 is connected to, for example, a driver state detection unit 12041 for detecting a state of a driver. The driver state detection unit 12041 includes, for example, a camera which images the driver, and the vehicle interior information detection unit 12040 may calculate a driver's fatigue level or concentration level or may determine whether or not the driver is dozing on the basis of detection information input from the driver state detection unit 12041.

The microcomputer 12051 may calculate a control target value of the driving force generating device, the steering mechanism, or the braking device on the basis of the information inside and outside the vehicle obtained by the vehicle exterior information detection unit 12030 or the vehicle interior information detection unit 12040, and output a control instruction to the drive system control unit 12010. For example, the microcomputer 12051 may perform cooperative control for realizing functions of advanced driver assistance system (ADAS) including collision avoidance or impact attenuation of the vehicle, following travel based on the distance between the vehicles, vehicle speed maintaining travel, vehicle collision warning, vehicle lane departure warning or the like.

Furthermore, the microcomputer 12051 may perform the cooperative control for realizing automatic driving and the like to autonomously travel independent from the operation of the driver by controlling the driving force generating device, the steering mechanism, the braking device or the like on the basis of the information around the vehicle obtained by the vehicle exterior information detection unit 12030 or the vehicle interior information detection unit 12040.

Furthermore, the microcomputer 12051 may output the control instruction to the body system control unit 12020 on the basis of the information outside the vehicle obtained by the vehicle exterior information detection unit 12030. For example, the microcomputer 12051 may perform the cooperative control to realize glare protection such as controlling the head light according to a position of a preceding vehicle or an oncoming vehicle detected by the vehicle exterior information detection unit 12030 to switch a high beam to a low beam.

The audio image output unit 12052 transmits at least one of audio or image output signal to an output device capable of visually or audibly notifying an occupant of the vehicle or the outside the vehicle of the information. In the example in FIG. 32, as the output device, an audio speaker 12061, a display unit 12062, and an instrument panel 12063 are illustrated. The display unit 12062 may include at least one of an on-board display or a head-up display, for example.

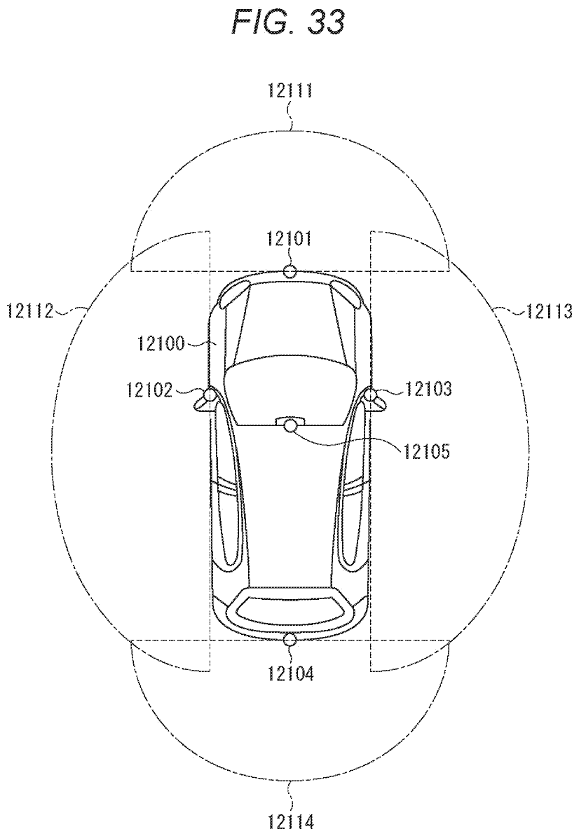

FIG. 33 is a view illustrating an example of an installation position of the imaging unit 12031.

In FIG. 33, the vehicle 12100 includes imaging units 12101, 12102, 12103, 12104, and 12105 as the imaging unit 12031.

The imaging units 12101, 12102, 12103, 12104, and 12105 are provided in positions such as, for example, a front nose, a side mirror, a rear bumper, a rear door, and an upper portion of a front windshield in a vehicle interior of the vehicle 12100. The imaging unit 12101 provided on the front nose and the imaging unit 12105 provided in the upper portion of the front windshield in the vehicle interior principally obtain images in front of the vehicle 12100. The imaging units 12102 and 12103 provided on the side mirrors principally obtain images of the sides of the vehicle 12100. The imaging unit 12104 provided on the rear bumper or the rear door principally obtains an image behind the vehicle 12100. The images in front obtained by the imaging units 12101 and 12105 are principally used for detecting a preceding vehicle, a pedestrian, an obstacle, a traffic signal, a traffic sign, a lane or the like.

Note that, in FIG. 33, an example of imaging ranges of the imaging units 12101 to 12104 is illustrated. An imaging range 12111 indicates the imaging range of the imaging unit 12101 provided on the front nose, imaging ranges 12112 and 12113 indicate the imaging ranges of the imaging units 12102 and 12103 provided on the side mirrors, and an imaging range 12114 indicates the imaging range of the imaging unit 12104 provided on the rear bumper or the rear door. For example, image data taken by the imaging units 12101 to 12104 are superimposed, so that an overlooking image of the vehicle 12100 as seen from above is obtained.

At least one of the imaging units 12101 to 12104 may have a function of obtaining distance information. For example, at least one of the imaging units 12101 to 12104 may be a stereo camera including a plurality of imaging elements, or may be an imaging element including pixels for phase difference detection.

For example, the microcomputer 12051 may extract especially a closest solid object on a traveling path of the vehicle 12100, the solid object traveling at a predetermined speed (for example, 0 km/h or higher) in a direction substantially the same as that of the vehicle 12100 as the preceding vehicle by obtaining a distance to each solid object in the imaging ranges 12111 to 12114 and a change in time of the distance (relative speed relative to the vehicle 12100) on the basis of the distance information obtained from the imaging units 12101 to 12104. Moreover, the microcomputer 12051 may set the distance between the vehicles to be secured in advance from the preceding vehicle, and may perform automatic brake control (including following stop control), automatic acceleration control (including following start control) and the like. In this manner, it is possible to perform the cooperative control for realizing the automatic driving and the like to autonomously travel independent from the operation of the driver.

For example, the microcomputer 12051 may extract solid object data regarding the solid object while sorting the same into a motorcycle, a standard vehicle, a large-sized vehicle, a pedestrian, and other solid objects such as a utility pole on the basis of the distance information obtained from the imaging units 12101 to 12104 and use for automatically avoiding obstacles. For example, the microcomputer 12051 discriminates the obstacles around the vehicle 12100 into an obstacle visible to a driver of the vehicle 12100 and an obstacle difficult to see. Then, the microcomputer 12051 determines a collision risk indicating a degree of risk of collision with each obstacle, and when the collision risk is equal to or higher than a set value and there is a possibility of collision, this may perform driving assistance for avoiding the collision by outputting an alarm to the driver via the audio speaker 12061 and the display unit 12062 or performing forced deceleration or avoidance steering via the drive system control unit 12010.

At least one of the imaging units 12101 to 12104 may be an infrared camera for detecting infrared rays. For example, the microcomputer 12051 may recognize a pedestrian by determining whether or not there is a pedestrian in the images taken by the imaging units 12101 to 12104. Such pedestrian recognition is carried out, for example, by a procedure of extracting feature points in the images taken by the imaging units 12101 to 12104 as the infrared cameras and a procedure of performing pattern matching processing on a series of feature points indicating an outline of an object to discriminate whether or not this is a pedestrian. When the microcomputer 12051 determines that there is a pedestrian in the images taken by the imaging units 12101 to 12104 and recognizes the pedestrian, the audio image output unit 12052 controls the display unit 12062 to superimpose a rectangular contour for emphasis on the recognized pedestrian. Furthermore, the audio image output unit 12052 may control the display unit 12062 to display an icon and the like indicating the pedestrian at a desired position.

An example of the vehicle control system to which the technology according to the present disclosure may be applied is described above. The technology according to the present disclosure may be applied to the imaging unit 12031 and the like out of the configurations described above. By applying the technology according to the present disclosure, it is possible to take a higher-quality image with high sensitivity while suppressing occurrence of flare due to reflected light.

<Combination Example of Configurations>

Note that, the present technology may also have following configurations.

(1)

A sensor device provided with:

a semiconductor substrate on which a photodiode is formed;

a filter included in a multilayer structure stacked on a light-receiving surface side of the semiconductor substrate; and

a moth-eye structure arranged on an outermost surface above the filter.

(2)

The sensor device according to (1) described above, in which the surface of the substrate on which the moth-eye structure is arranged is formed to be effectively flat.

(3)

The sensor device according to (1) or (2) described above,

in which the filter performs spectroscopy into a plurality of spectral components in multiple bands of three primary colors of light or more.

(4)

The sensor device according to any one of (1) to (3) described above,

in which the filter is a surface plasmon resonance filter.

(5)

The sensor device according to any one of (1) to (3) described above,

in which the filter is a Fabry-Perot resonator filter.

(6)

The sensor device according to any one of (1) to (5) described above,

in which the moth-eye structure is formed by transferring a fine structure pattern formed on a nanoimprinting mold to a resin material applied to an outermost surface of the multilayer structure stacked on the light-receiving surface side of the semiconductor substrate.

(7)

The sensor device according to any one of (1) to (5) described above,

in which the moth-eye structure is obtained such that a fine structure pattern is formed on a resin member separately from the multilayer structure stacked on the light-receiving surface side of the semiconductor substrate to be adhered to the multilayer structure stacked on the light-receiving surface side of the semiconductor substrate.

(8)

The sensor device according to (7) described above,

in which a stress relaxation resin material film is stacked between the resin member on which the fine structure pattern of the moth-eye structure is formed and an inorganic material of the multilayer structure stacked on the light-receiving surface side of the semiconductor substrate.

(9)

An electronic device provided with a sensor device including:

a semiconductor substrate on which a photodiode is formed;

a filter included in a multilayer structure stacked on a light-receiving surface side of the semiconductor substrate; and

a moth-eye structure arranged on an outermost surface above the filter.

(10)

The electronic device according to (9) described above,

in which the filter performs spectroscopy into a plurality of spectral components in multiple bands of three primary colors of light or more, and

is able to perform multi-spectroscopy or hyperspectral spectroscopy.

Note that, the embodiments are not limited to the above-described embodiments and may be variously changed without departing from the gist of the present disclosure. Furthermore, the effects described in this specification are illustrative only and are not limitative; there may also be another effect.

### REFERENCE SIGNS LIST

21 Sensor chip
22 Pixel
23 Photodiode
24 Semiconductor substrate
25 Antireflection film
26 Silicon oxide film
27 Surface plasmon resonance filter
28 Silicon oxynitride film
29 Silicon nitride film
30 Moth-eye structure
31 Light-shielding film
32 Aluminum film
33 Fine structure
41 Fabry-Perot resonator
42 Resonator
43 Half mirror layer
51 Ultraviolet curable resin
52 Mold
61 Stress relaxation resin material film
62 On-chip color filter

1. A sensor device comprising:
a semiconductor substrate on which a photodiode is formed;
a filter included in a multilayer structure stacked on a light-receiving surface side of the semiconductor substrate; and
a moth-eye structure arranged on an outermost surface above the filter.

2. The sensor device according to claim 1,
wherein the surface of the substrate on which the moth-eye structure is arranged is formed to be effectively flat.

3. The sensor device according to claim 1,
wherein the filter performs spectroscopy into a plurality of spectral components in multiple bands of three primary colors of light or more.

4. The sensor device according to claim 3,
wherein the filter is a surface plasmon resonance filter.

5. The sensor device according to claim 3,
wherein the filter is a Fabry-Perot resonator filter.

6. The sensor device according to claim 1,
wherein the moth-eye structure is formed by transferring a fine structure pattern formed on a nanoimprinting mold to a resin material applied to an outermost surface of the multilayer structure stacked on the light-receiving surface side of the semiconductor substrate.

7. The sensor device according to claim 1,
wherein the moth-eye structure is obtained such that a fine structure pattern is formed on a resin member separately from the multilayer structure stacked on the light-receiving surface side of the semiconductor substrate to be adhered to the multilayer structure stacked on the light-receiving surface side of the semiconductor substrate.

8. The sensor device according to claim 7,
wherein a stress relaxation resin material film is stacked between the resin member on which the fine structure pattern of the moth-eye structure is formed and an inorganic material of the multilayer structure stacked on the light-receiving surface side of the semiconductor substrate.

9. An electronic device comprising a sensor device including:
a semiconductor substrate on which a photodiode is formed;
a filter included in a multilayer structure stacked on a light-receiving surface side of the semiconductor substrate; and
a moth-eye structure arranged on an outermost surface above the filter.

10. The electronic device according to claim 9,
wherein the filter performs spectroscopy into a plurality of spectral components in multiple bands of three primary colors of light or more, and
is able to perform multi-spectroscopy or hyperspectral spectroscopy.
